(19) United States
(12) Patent Application Publication
(10) Pub. No.: US 2026/0318998 A1
(43) Pub. Date: Oct. 15, 2026

(54) MONITORING STATE OF CHARGE OF ENERGY SOURCES

(71) Applicant: TAE Power Solutions, LLC, Foothill Ranch, CA (US)

(72) Inventors: Anthony O'CARROLL, Birmingham West Midlands (GB); Simon Thomas ANSELL, Birmingham West Midlands (GB)

(21) Appl. No.: 19/483,727

(22) PCT Filed: May 9, 2024
(86) PCT No.: PCT/US2024/028604

§ 371 Date: Nov. 12, 2025

Related U.S. Application Data
(60) Provisional application No. 63/501,947, filed on May 12, 2023.

(51) Int. Cl. G01R 31/3832; H01M 10/42; H01M 10/48

(52) U.S. Cl. CPC G01R 31/3832; H01M 10/425; H01M 10/48; H01M 2010/4271

(57) ABSTRACT

Systems, devices, and methods for estimating states of charge of energy sources using multiple integrator circuits. During a first state, a first integrator circuit can integrate current measurement signals while the output of a second integrator circuit remains constant such that a device can obtain an integrated voltage value from the second integrator circuit. During a second state, the second integrator circuit can integrate current measurement signals while the output of the first integrator circuit remains constant such that a device can obtain an integrated voltage value from the first integrator circuit.

### CROSS-REFERENCE TO RELATED APPLICATIONS

This application claims the benefit of the U.S. Provisional Patent Application No. 63/501,947 filed May 12, 2023, which is incorporated herein by reference in its entirety.

### FIELD

The subject matter described herein relates generally to systems, devices, and methods that facilitate monitoring the State of Charge (SOC) of energy sources.

### BACKGROUND

Electrical energy storage systems are an important facet in the worldwide transition to cleaner forms of energy. Electrical energy storage systems are found in a host of stationary and mobile applications. An electrical energy storage system in the form of a battery pack or rack can be used to power hybrid and fully electric vehicles, and can be used to store power generated by the vehicle (e.g., through the use of regenerative braking).

It is often critical to accurately estimate the SOC of batteries and other energy sources. For example, inaccurate estimation of SOC of batteries can cause excessive charging and discharging of the batteries, resulting in degraded performance, overheating, fires and/or explosions, increased battery impedance, and decreased lifespans of the batteries. Inaccurate estimation of SOC can also result in unexpected downtime of systems powered by the energy sources, such as loss of propulsion of electric vehicles although the estimated SOC indicates sufficient charge to maintain propulsion.

In general, the SOC of an energy source can be estimated using models that are typically based on voltage measurements, measurements of the current into and out of the energy source, and/or other factors, such as temperature of the energy source. These measurements must be accurate in order for the SOC models to output an accurate SOC. Some techniques for performing the current measurements use a measuring circuit to monitor voltage across a sensing element to determine the current into the energy source and the current out of the energy source, which often results in inaccuracies due to the size of the circuit and latency in reporting the current values.

For these and other reasons, needs exist for improved systems, devices, and methods for accurately estimating the SOC of energy sources.

### SUMMARY

Example embodiments of systems, devices, and methods are provided herein for monitoring the SOC of energy sources, e.g., energy sources of module-based energy systems, battery packs, individual batteries, individual battery cells, and/or other arrangements of one or more energy sources. In general, the SOC of an energy source can be estimated based on current measurements for the energy source, and optionally additional information such as voltage measurements for the energy source and/or the temperature measurements for the energy source.

An SOC monitor device is configured to receive current measurement signals that represent current measurements for an energy source and estimate the SOC of the energy source based on the current measurement signals and optionally other signals, e.g., voltage and/or temperature measurements. The SOC monitor device can include a multi-integrator circuit that includes multiple integrator circuits, which can be coupled in parallel. Each integrator circuit is configured to integrate current measurements for the energy source to generate an integrated voltage value that is proportional to the charge drawn from or supplied to the energy source over a time period in which the current measurements are made.

The SOC monitor device can also include an SOC measurement control device (SMCD) that is configured to toggle between multiple states in which an integrator circuit is either generating the integrated voltage value based on the current measurements or maintaining a constant voltage value for retrieval by the measurement control device. For example, if the SOC monitor device includes two integrator circuits, the measurement control device can toggle between two states including a first state in which a first integrator circuit integrates current measurements to generate the integrated voltage value and a second state in which a second integrator circuit integrates current measurements to generate the integrated voltage value. Based on being in the first state or the second state, the measurement control device can selectively obtain the integrated voltage value of the first integrator circuit or the integrated voltage value of the second integrator circuit.

In particular, when the SMCD is in the first state, the first integrator circuit generates the integrated voltage value by monitoring current measurement signals obtained from a current sensing element (e.g., a resistor) and the second integrator circuit holds a final integrated voltage value for a previous time period in which the SMCD was in the second state. When SMCD is in the second state, the second integrator circuit generates the integrated voltage value by monitoring current obtained from the current sensing element and the first integrator circuit holds a final integrated voltage value for a previous time period in which the measurement control device was in the first state. The SMCD can toggle between the two states by controlling one or more switch circuits.

By toggling back and forth between the different states in this manner, the current measurement signals received from the current sensing element are monitored and integrated by one of the integrator circuits without interruption, while allowing the integrator circuits to maintain integrated voltage values for periods of time to facilitate collection of the integrated voltage values by the measurement control device. For example, if a single integrator device is used, the integrator device would have to pause integration of current measurements for some time while reading and reporting the integrated voltage value from the integrator circuit, resulting in some current measurements being excluded from the integration. For example, some high frequency elements of a current waveform may be missed during cyclical holds for reporting the integrated voltage values. This results in inaccurate integrated voltage values and inaccurate SOC estimations that are based on these integrated voltage values. Using multiple integrator circuits as described herein facilities more accurate estimation of SOC of energy sources using current measurements taken at all times (or at least almost all times) during SOC monitoring.

Other systems, devices, methods, features and advantages of the subject matter described herein will be apparent to one with skill in the art upon examination of the following figures and detailed description. It is intended that all such additional systems, methods, features and advantages be included within this description, and be within the scope of the subject matter described herein. In no way should the features of the example embodiments be construed as limiting the appended claims, absent express recitation of those features in the claims.

### BRIEF DESCRIPTION OF FIGURES

The details of the subject matter set forth herein, both as to its structure and operation, may be apparent by study of the accompanying figures, in which like reference numerals refer to like parts. The components in the figures are not necessarily to scale, emphasis instead being placed upon illustrating the principles of the subject matter. Moreover, all illustrations are intended to convey concepts, where relative sizes, shapes and other detailed attributes may be illustrated schematically rather than literally or precisely.

FIGS. 1A-1C are block diagrams depicting example embodiments of a modular energy system.

FIGS. 1D-1E are block diagrams depicting example embodiments of control devices for an energy system.

FIGS. 1F-1G are block diagrams depicting example embodiments of modular energy systems coupled with a load and a charge source.

FIGS. 2A-2B are block diagrams depicting example embodiments of a module and control system within an energy system.

FIG. 2C is a block diagram depicting an example embodiment of a physical configuration of a module.

FIG. 2D is a block diagram depicting an example embodiment of a physical configuration of a modular energy system.

FIGS. 3A-3C are block diagrams depicting example embodiments of modules having various electrical configurations.

FIGS. 4A-4F are schematic views depicting example embodiments of energy sources.

FIGS. 5A-5C are schematic views depicting example embodiments of energy buffers.

FIGS. 6A-6C are schematic views depicting example embodiments of converters.

FIGS. 7A-7E are block diagrams depicting example embodiments of modular energy systems having various topologies.

FIG. 8A is a plot depicting an example output voltage of a module.

FIG. 8B is a plot depicting an example multilevel output voltage of an array of modules.

FIG. 8C is a plot depicting an example reference signal and carrier signals usable in a pulse width modulation control technique.

FIG. 8D is a plot depicting example reference signals and carrier signals usable in a pulse width modulation control technique.

FIG. 8E is a plot depicting example switch signals generated according to a pulse width modulation control technique.

FIG. 8F as a plot depicting an example multilevel output voltage generated by superposition of output voltages from an array of modules under a pulse width modulation control technique.

FIGS. 9A-9B are block diagrams depicting example embodiments of controllers for a modular energy system.

FIG. 10A is a block diagram depicting an example embodiment of a multiphase modular energy system having interconnection module.

FIG. 10B is a schematic diagram depicting an example embodiment of an interconnection module in the multiphase embodiment of FIG. 10A.

FIG. 10C is a block diagram depicting an example embodiment of a modular energy system having two subsystems connected together by interconnection modules.

FIG. 10D is a block diagram depicting an example embodiment of a three-phase modular energy system having interconnection modules supplying auxiliary loads.

FIG. 10E is a schematic view depicting an example embodiment of the interconnection modules in the multiphase embodiment of FIG. 10D.

FIG. 10F is a block diagram depicting another example embodiment of a three-phase modular energy system having interconnection modules supplying auxiliary loads.

FIG. 11A is a block diagram depicting an example embodiment of a SOC monitor device.

FIG. 11B is a schematic diagram depicting an example embodiment of an integrator circuit.

FIG. 12 is a flowchart depicting an example embodiment of a method of monitoring state of charge of an energy source.

### DETAILED DESCRIPTION

Before the present subject matter is described in detail, it is to be understood that this disclosure is not limited to the particular embodiments described, as such may, of course, vary. The terminology used herein is for the purpose of describing particular embodiments only, and is not intended to be limiting, since the scope of the present disclosure will be limited only by the appended claims.

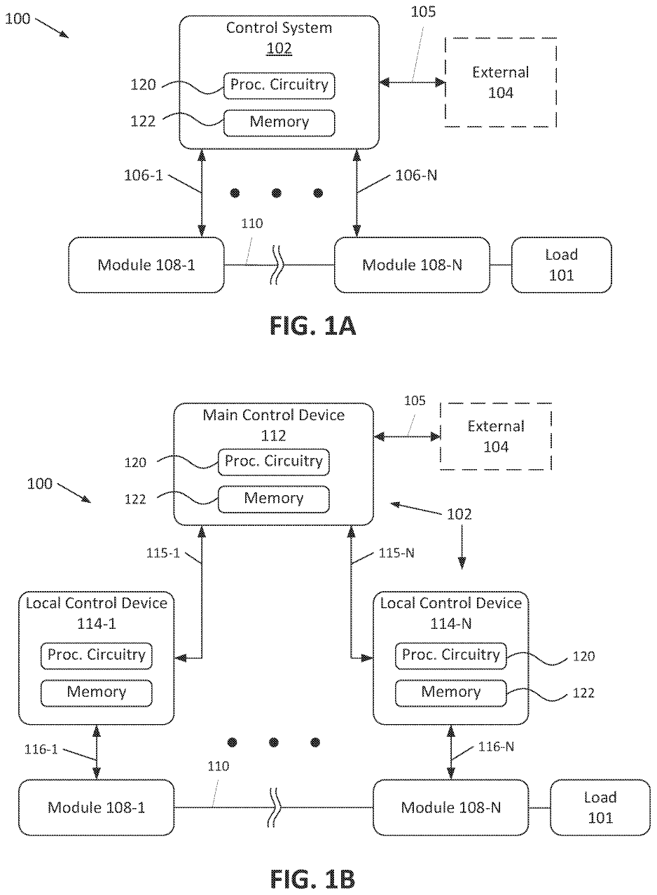

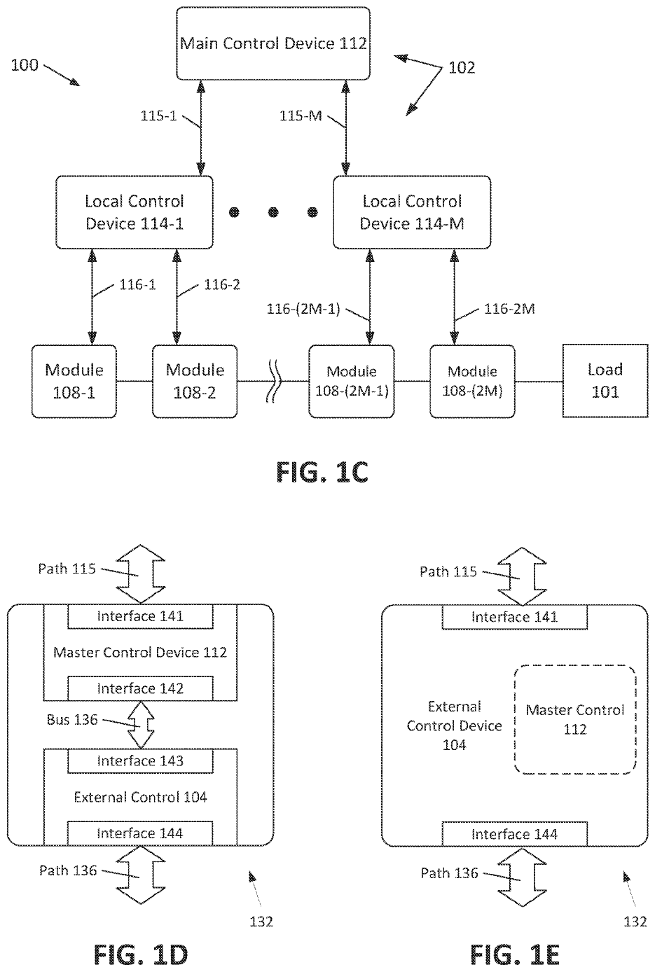

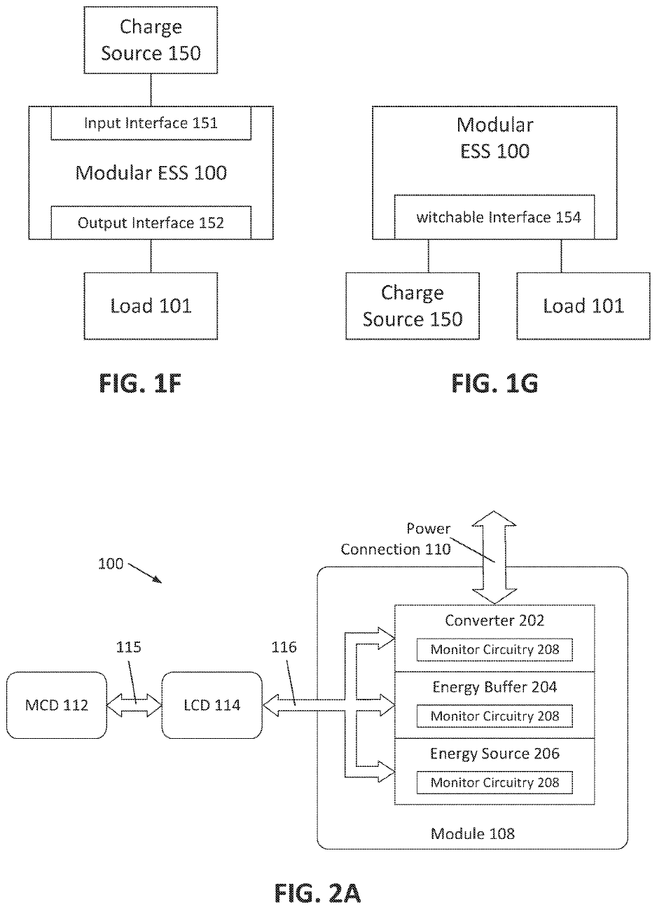

Before describing the example embodiments pertaining to modular energy systems that include an SOC monitor device for estimating the SOC of energy sources of modules using a multi-integrator circuit, it is first useful to describe these underlying systems in greater detail. With reference to FIGS. 1A through 10F, the following sections describe various applications in which embodiments of the modular energy systems can be implemented, embodiments of control systems or devices for the modular energy systems, configurations of the modular energy system embodiments with respect to charging sources and loads, embodiments of individual modules, embodiments of topologies for arrangement of the modules within the systems, embodiments of control methodologies, embodiments of balancing operating characteristics of modules within the systems, and embodiments of the use of interconnection modules.

### Examples of Applications

Stationary applications are those in which the modular energy system is located in a fixed location during use, although it may be capable of being transported to alternative locations when not in use. The module-based energy system resides in a static location while providing electrical energy for consumption by one or more other entities, or storing or buffering energy for later consumption. Examples of stationary applications in which the embodiments disclosed herein can be used include, but are not limited to: energy systems for use by or within one or more residential structures or locales, energy systems for use by or within one or more industrial structures or locales, energy systems for use by or within one or more commercial structures or locales, energy systems for use by or within one or more governmental structures or locales (including both military and non-military uses), energy systems for charging the mobile applications described below (e.g., a charge source or a charging station), and systems that convert solar power, wind, geothermal energy, fossil fuels, or nuclear reactions into electricity for storage. Stationary applications often supply loads such as grids and microgrids, motors, and data centers. A stationary energy system can be used in either a storage or non-storage role.

Mobile applications, sometimes referred to as traction applications, are generally ones where a module-based energy system is located on or within an entity, and stores and provides electrical energy for conversion into motive force by a motor to move or assist in moving that entity. Examples of mobile entities with which the embodiments disclosed herein can be used include, but are not limited to, electric and/or hybrid entities that move over or under land, over or under sea, above and out of contact with land or sea (e.g., flying or hovering in the air), or through outer space. Examples of mobile entities with which the embodiments disclosed herein can be used include, but are not limited to, vehicles, trains, trams, ships, vessels, aircraft, and spacecraft. Examples of mobile vehicles with which the embodiments disclosed herein can be used include, but are not limited to, those having only one wheel or track, those having only two-wheels or tracks, those having only three wheels or tracks, those having only four wheels or tracks, and those having five or more wheels or tracks. Examples of mobile entities with which the embodiments disclosed herein can be used include, but are not limited to, a car, a bus, a truck, a motorcycle, a scooter, a bicycle, an industrial vehicle, a mining vehicle, a flying vehicle (e.g., a plane, a helicopter, a drone, etc.), a maritime vessel (e.g., commercial shipping vessels, ships, yachts, boats or other watercraft), a submarine, a locomotive or rail-based vehicle (e.g., a train, a tram, etc.), a military vehicle, a spacecraft, and a satellite.

In describing embodiments herein, reference may be made to a particular stationary application (e.g., grid, micro-grid, data centers, cloud computing environments) or mobile application (e.g., an electric car). Such references are made for ease of explanation and do not mean that a particular embodiment is limited for use to only that particular mobile or stationary application. Embodiments of systems providing power to a motor can be used in both mobile and stationary applications. While certain configurations may be more suitable to some applications over others, all example embodiments disclosed herein are capable of use in both mobile and stationary applications unless otherwise noted.

### Module-Based Energy System Examples

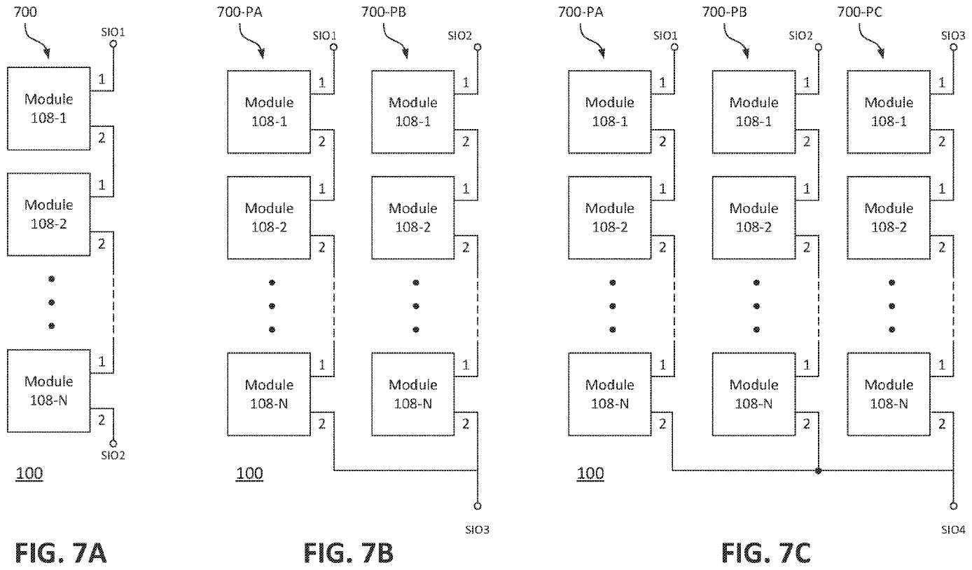

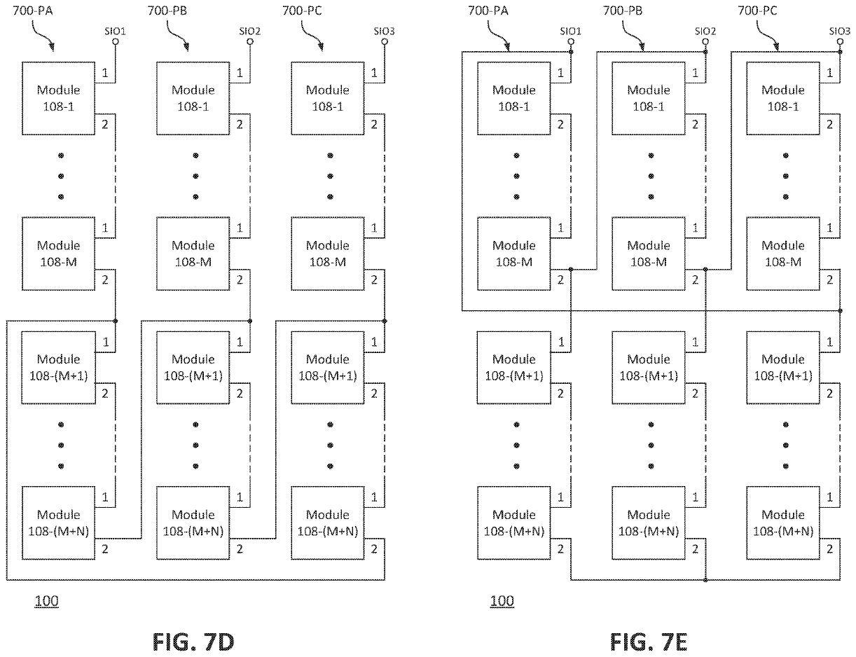

FIG. 1A is a block diagram depicts an example embodiment of a module-based energy system 100. Here, system 100 includes control system 102 communicatively coupled with N converter-source modules 108-1 through 108-N, over communication paths or links 106-1 through 106-N, respectively. Modules 108 are configured to store energy and output the energy as needed to a load 101 (or other modules 108). In these embodiments, any number of two or more modules 108 can be used (e.g., N is greater than or equal to two). Modules 108 can be connected to each other in a variety of manners as will be described in more detail with respect to FIGS. 7A-7E. For ease of illustration, in FIGS. 1A-1C, modules 108 are shown connected in series, or as a one dimensional array, where the Nth module is coupled to load 101.

System 100 is configured to supply power to load 101. Load 101 can be any type of load such as a motor or a grid. System 100 is also configured to store power received from a charge source. FIG. 1F is a block diagram depicting an example embodiment of system 100 with a power input interface 151 for receiving power from a charge source 150 and a power output interface for outputting power to load 101. In this embodiment system 100 can receive and store power over interface 151 at the same time as outputting power over interface 152. FIG. 1G is a block diagram depicting another example embodiment of system 100 with a switchable interface 154. In this embodiment, system 100 can select, or be instructed to select, between receiving power from charge source 150 and outputting power to load 101. System 100 can be configured to supply multiple loads 101, including both primary and auxiliary loads, and/or receive power from multiple charge sources 150 (e.g., a utility-operated power grid and a local renewable energy source (e.g., solar)).

FIG. 1B depicts another example embodiment of system 100. Here, control system 102 is implemented as a main control device (MCD) 112 communicatively coupled with N different local control devices (LCDs) 114-1 through 114-N over communication paths or links 115-1 through 115-N, respectively. Each LCD 114-1 through 114-N is communicatively coupled with one module 108-1 through 108-N over communication paths or links 116-1 through 116-N, respectively, such that there is a 1:1 relationship between LCDs 114 and modules 108.

FIG. 1C depicts another example embodiment of system 100. Here, MCD 112 is communicatively coupled with M different LCDs 114-1 to 114-M over communication paths or links 115-1 to 115-M, respectively. Each LCD 114 can be coupled with and control two or more modules 108. In the example shown here, each LCD 114 is communicatively coupled with two modules 108, such that M LCDs 114-1 to 114-M are coupled with 2M modules 108-1 through 108-2M over communication paths or links 116-1 to 116-2M, respectively.

Control system 102 can be configured as a single device (e.g., FIG. 1A) for the entire system 100 or can be distributed across or implemented as multiple devices (e.g., FIGS. 1B-1C). In some embodiments, control system 102 can be distributed between LCDs 114 associated with the modules 108, such that no MCD 112 is necessary and can be omitted from system 100.

Control system 102 can be configured to execute control using software (instructions stored in memory that are executable by processing circuitry), hardware, or a combination thereof. The one or more devices of control system 102 can each include processing circuitry 120 and memory 122 as shown here. Example implementations of processing circuitry and memory are described further below.

Control system 102 can have a communicative interface for communicating with devices 104 external to system 100 over a communication link or path 105. For example, control system 102 (e.g., MCD 112) can output data or information about system 100 to another control device 104 (e.g., the Electronic Control Unit (ECU) or Motor Control Unit (MCU) of a vehicle in a mobile application, grid controller in a stationary application, etc.).

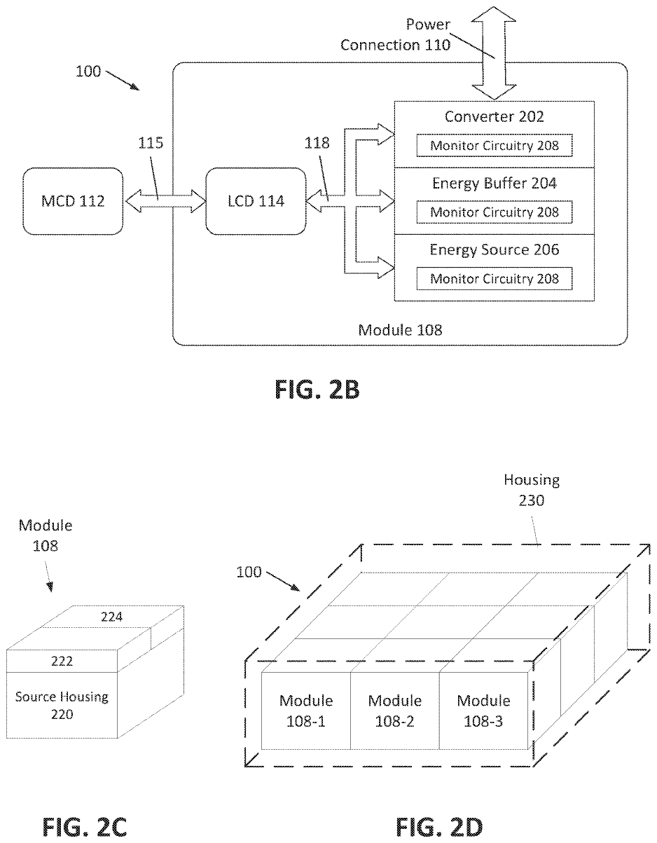

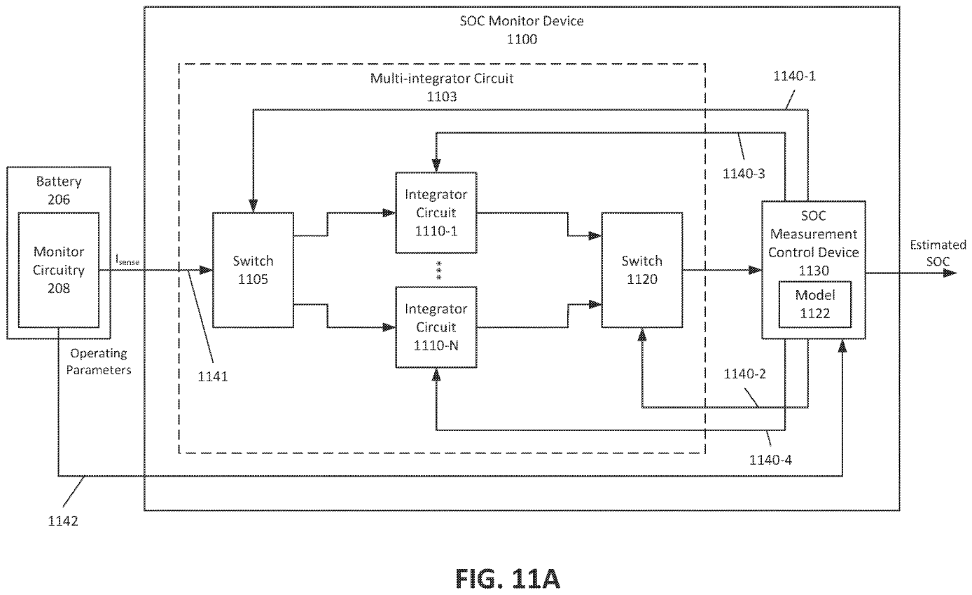

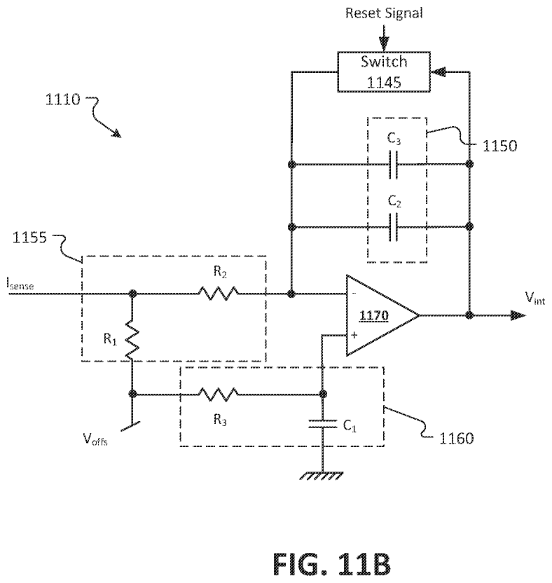

Communication paths or links 105, 106, 115, 116, 118 (FIG. 2B), 1140, 1141, and 1142 (FIG. 11A) can each be wired (e.g., electrical, optical) or wireless communication paths that communicate data or information bidirectionally, in parallel or series fashion. Data can be communicated in a standardized (e.g., IEEE, ANSI) or custom (e.g., proprietary) format. In automotive applications, communication paths 115 can be configured to communicate according to FlexRay or CAN protocols. Communication paths 106, 115, 116, and 118 can also provide wired power to directly supply the operating power for system 102 from one or more modules 108. For example, the operating power for each LCD 114 can be supplied only by the one or more modules 108 to which that LCD 114 is connected and the operating power for MCD 112 can be supplied indirectly from one or more of modules 108 (e.g., such as through a car's power network).

Control system 102 is configured to control one or more modules 108 based on status information received from the same or different one or more of modules 108. Control can also be based on one or more other factors, such as requirements of load 101. Controllable aspects include, but are not limited to, one or more of voltage, current, phase, and/or output power of each module 108.

Status information of every module 108 in system 100 can be communicated to control system 102, which can independently control every module 108-1 . . . 108-N. Other variations are possible. For example, a particular module 108 (or subset of modules 108) can be controlled based on status information of that particular module 108 (or subset), based on status information of a different module 108 that is not that particular module 108 (or subset), based on status information of all modules 108 other than that particular module 108 (or subset), based on status information of that particular module 108 (or subset) and status information of at least one other module 108 that is not that particular module 108 (or subset), or based on status information of all modules 108 in system 100.

The status information can be information about one or more aspects, characteristics, or parameters of each module 108. Types of status information include, but are not limited to, the following aspects of a module 108 or one or more components thereof (e.g., energy source, energy buffer, converter, monitor circuitry): State of Charge (SOC) (e.g., the level of charge of an energy source relative to its capacity, such as a fraction or percent) of the one or more energy sources of the module, State of Health (SOH) (e.g., a figure of merit of the condition of an energy source compared to its ideal conditions) of the one or more energy sources of the module, temperature of the one or more energy sources or other components of the module, capacity of the one or more energy sources of the module, voltage of the one or more energy sources and/or other components of the module, current of the one or more energy sources and/or other components of the module, State of Power (SOP) (e.g., the available power limitation of the energy source during discharge and/or charge), State of Energy (SOE) (e.g., the present level of available energy of an energy source relative to the maximum available energy of the source), and/or the presence of absence of a fault in any one or more of the components of the module.

LCDs 114 can be configured to receive the status information from each module 108, or determine the status information from monitored signals or data received from or within each module 108, and communicate that information to MCD 112. In some embodiments, each LCD 114 communicates raw collected data to MCD 112, which then algorithmically determines the status information on the basis of that raw data. MCD 112 can then use the status information of modules 108 to make control determinations accordingly. The determinations may take the form of instructions, commands, or other information (such as a modulation index described herein) that can be utilized by LCDs 114 to either maintain or adjust the operation of each module 108.

For example, MCD 112 may receive status information and assess that information to determine a difference between at least one module 108 (e.g., a component thereof) and at least one or more other modules 108 (e.g., comparable components thereof). For example, MCD 112 may determine that a particular module 108 is operating with one of the following conditions as compared to one or more other modules 108: with a relatively lower or higher SOC, with a relatively lower or higher SOH, with a relatively lower or higher capacity, with a relatively lower or higher voltage, with a relatively lower or higher current, with a relatively lower or higher temperature, or with or without a fault. In such examples, MCD 112 can output control information that causes the relevant aspect (e.g., output voltage, current, power, temperature) of that particular module 108 to be reduced or increased (depending on the condition). In this manner, the utilization of an outlier module 108 (e.g., operating with a relatively lower SOC or higher temperature), can be reduced so as to cause the relevant parameter of that module 108 (e.g., SOC or temperature) to converge towards that of one or more other modules 108.

The determination of whether to adjust the operation of a particular module 108 can be made by comparison of the status information to predetermined thresholds, limits, or conditions, and not necessarily by comparison to statuses of other modules 108. The predetermined thresholds, limits, or conditions can be static thresholds, limits, or conditions, such as those set by the manufacturer that do not change during use. The predetermined thresholds, limits, or conditions can be dynamic thresholds, limits, or conditions, that are permitted to change, or that do change, during use. For example, MCD 112 can adjust the operation of a module 108 if the status information for that module 108 indicates it to be operating in violation (e.g., above or below) of a predetermined threshold or limit, or outside of a predetermined range of acceptable operating conditions. Similarly, MCD 112 can adjust the operation of a module 108 if the status information for that module 108 indicates the presence of an actual or potential fault (e.g., an alarm, or warning) or indicates the absence or removal of an actual or potential fault. Examples of a fault include, but are not limited to, an actual failure of a component, a potential failure of a component, a short circuit or other excessive current condition, an open circuit, an excessive voltage condition, a failure to receive a communication, the receipt of corrupted data, and the like. Depending on the type and severity of the fault, the faulty module's utilization can be decreased to avoid damaging the module, or the module's utilization can be ceased altogether. For example, if a fault occurs in a given module, then MCD 112 or LCD 114 can cause that module to enter a bypass state as described herein.

MCD 112 can control modules 108 within system 100 to achieve or converge towards a desired target. The target can be, for example, operation of all modules 108 at the same or similar levels with respect to each other, or within predetermined thresholds limits, or conditions. This process is also referred to as balancing or seeking to achieve balance in the operation or operating characteristics of modules 108. The term “balance” as used herein does not require absolute equality between modules 108 or components thereof, but rather is used in a broad sense to convey that operation of system 100 can be managed so as to actively reduce disparities in operation (or operative state) between modules 108 that would otherwise exist.

MCD 112 can communicate control information to LCD 114 for the purpose of controlling the modules 108 associated with the LCD 114. The control information can be, e.g., a modulation index and a reference signal as described herein, a modulated reference signal, or otherwise. Each LCD 114 can use (e.g., receive and process) the control information to generate switch signals that control operation of one or more components (e.g., a converter) within the associated module(s) 108. In some embodiments, MCD 112 generates the switch signals directly and outputs them to LCD 114, which relays the switch signals to the intended module component.

All or a portion of control system 102 can be combined with a system external control device 104 that controls one or more other aspects of the mobile or stationary application. When integrated in this shared or common control device (or subsystem), control of system 100 can be implemented in any desired fashion, such as one or more software applications executed by processing circuitry of the shared device, with hardware of the shared device, or a combination thereof. Non-exhaustive examples of external control devices 104 include: a vehicular ECU or MCU having control capability for one or more other vehicular functions (e.g., motor control, driver interface control, traction control, etc.); a grid or micro-grid controller having responsibility for one or more other power management functions (e.g., load interfacing, load power requirement forecasting, transmission and switching, interface with charge sources (e.g., diesel, solar, wind), charge source power forecasting, back up source monitoring, asset dispatch, etc.); and a data center control subsystem (e.g., environmental control, network control, backup control, etc.).

FIGS. 1D and 1E are block diagrams depicting example embodiments of a shared or common control device (or system) 132 in which control system 102 can be implemented. In FIG. 1D, common control device 132 includes main control device 112 and external control device 104. Main control device 112 includes an interface 141 for communication with LCDs 114 over path 115, as well as an interface 142 for communication with external control device 104 over internal communication bus 136. External control device 104 includes an interface 143 for communication with main control device 112 over bus 136, and an interface 144 for communication with other entities (e.g., components of the vehicle or grid) of the overall application over communication path 136. In some embodiments, common control device 132 can be integrated as a common housing or package with devices 112 and 104 implemented as discrete integrated circuit (IC) chips or packages contained therein.

In FIG. 1E, external control device 104 acts as common control device 132, with the main control functionality implemented as a component within device 104. This component 112 can be or include software or other program instructions stored and/or hardcoded within memory of device 104 and executed by processing circuitry thereof. The component can also contain dedicated hardware. The component can be a self-contained module or core, with one or more internal hardware and/or software interfaces (e.g., application program interface (API)) for communication with the operating software of external control device 104. External control device 104 can manage communication with LCDs 114 over interface 141 and other devices over interface 144. In various embodiments, device 104/132 can be integrated as a single IC chip, can be integrated into multiple IC chips in a single package, or integrated as multiple semiconductor packages within a common housing.

In the embodiments of FIGS. 1D and 1E, the main control functionality of system 102 is shared in common device 132, however, other divisions of shared control or permitted. For example, part of the main control functionality can be distributed between common device 132 and a dedicated MCD 112. In another example, both the main control functionality and at least part of the local control functionality can be implemented in common device 132 (e.g., with remaining local control functionality implemented in LCDs 114). In some embodiments, all of control system 102 is implemented in common device (or subsystem) 132. In some embodiments, local control functionality is implemented within a device shared with another component of each module 108, such as a Battery Management System (BMS).

Examples of Modules within Cascaded Energy Systems

Module 108 can include one or more energy sources and a power electronics converter and, if desired, an energy buffer. FIGS. 2A-2B are block diagrams depicting additional example embodiments of system 100 with module 108 having a power converter 202, an energy buffer 204, and an energy source 206. Converter 202 can be a voltage converter or a current converter. The embodiments are described herein with reference to voltage converters, although the embodiments are not limited to such. Converter 202 can be configured to convert a direct current (DC) signal from energy source 204 into an alternating current (AC) signal and output it over power connection 110 (e.g., an inverter). Converter 202 can also receive an AC or DC signal over connection 110 and apply it to energy source 204 with either polarity in a continuous or pulsed form. Converter 202 can be or include an arrangement of switches (e.g., power transistors) such as a half bridge of full bridge (H-bridge). In some embodiments converter 202 includes only switches and the converter (and the module as a whole) does not include a transformer.

Converter 202 can be also (or alternatively) be configured to perform AC to DC conversion (e.g., a rectifier) such as to charge a DC energy source from an AC source, DC to DC conversion, and/or AC to AC conversion (e.g., in combination with an AC-DC converter). In some embodiments, such as to perform AC-AC conversion, converter 202 can include a transformer, either alone or in combination with one or more power semiconductors (e.g., switches, diodes, thyristors, and the like). In other embodiments, such as those where weight and cost is a significant factor, converter 202 can be configured to perform the conversions with only power switches, power diodes, or other semiconductor devices and without a transformer.

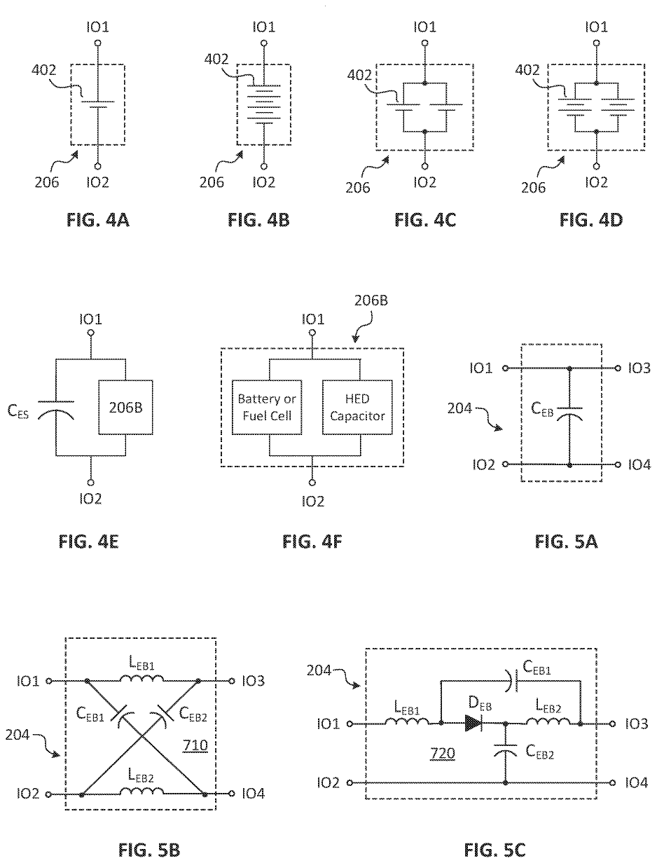

Energy source 206 is preferably a robust energy storage device capable of outputting direct current and having an energy density suitable for energy storage applications for electrically powered devices. Energy source 206 can be an electrochemical battery, such as a single battery cell or multiple battery cells connected together in a battery module or array, or any combination thereof. FIGS. 4A-4D are schematic diagrams depicting example embodiments of energy source 206 configured as a single battery cell 402 (FIG. 4A), a battery module with a series connection of multiple (e.g., four) cells 402 (FIG. 4B), a battery module with a parallel connection of single cells 402 (FIG. 4C), and a battery module with a parallel connection with legs having two cells 402 each (FIG. 4D). A non-exhaustive list of examples of battery types is set forth elsewhere herein.

Energy source 206 can also be a high energy density (HED) capacitor, such as an ultracapacitor or supercapacitor. An HED capacitor can be configured as a double layer capacitor (electrostatic charge storage), pseudocapacitor (electrochemical charge storage), hybrid capacitor (electrostatic and electrochemical), or otherwise, as opposed to a solid dielectric type of a typical electrolytic capacitor. The HED capacitor can have an energy density of 10 to 100 times (or higher) that of an electrolytic capacitor, in addition to a higher capacity. For example, HED capacitors can have a specific energy greater than 1.0 watt hours per kilogram (Wh/kg), and a capacitance greater than 10-100 farads (F). As with the batteries described with respect to FIGS. 4A-4D, energy source 206 can be configured as a single HED capacitor or multiple HED capacitors connected together in an array (e.g., series, parallel, or a combination thereof).

Energy source 206 can also be a fuel cell. The fuel cell can be a single fuel cell, multiple fuel cells connected in series or parallel, or a fuel cell module. Examples of fuel cell types include proton-exchange membrane fuel cells (PEMFC), phosphoric acid fuel cells (PAFC), solid acid fuel cells, alkaline fuel cells, high temperature fuel cells, solid oxide fuel cells, molten electrolyte fuel cells, and others. As with the batteries described with respect to FIGS. 4A-4D, energy source 206 can be configured as a single fuel cell or multiple fuel cells connected together in an array (e.g., series, parallel, or a combination thereof). The aforementioned examples of source classes (e.g., batteries, capacitors, and fuel cells) and types (e.g., chemistries and/or structural configurations within each class) are not intended to form an exhaustive list, and those of ordinary skill in the art will recognize other variants that fall within the scope of the present subject matter.

Energy buffer 204 can dampen or filter fluctuations in current across the DC line or link (e.g., +V_{DCL} and −V_{DCL} as described below), to assist in maintaining stability in the DC link voltage. These fluctuations can be relatively low (e.g., kilohertz) or high (e.g., megahertz) frequency fluctuations or harmonics caused by the switching of converter 202, or other transients. These fluctuations can be absorbed by buffer 204 instead of being passed to source 206 or to ports IO3 and IO4 of converter 202.

Power connection 110 is a connection for transferring energy or power to, from and through module 108. Module 108 can output energy from energy source 206 to power connection 110, where it can be transferred to other modules of the system or to a load. Module 108 can also receive energy from other modules 108 or a charging source (DC charger, single phase charger, multi-phase charger). Signals can also be passed through module 108 bypassing energy source 206. The routing of energy or power into and out of module 108 is performed by converter 202 under the control of LCD 114 (or another entity of system 102).

In the embodiment of FIG. 2A, LCD 114 is implemented as a component separate from module 108 (e.g., not within a shared module housing) and is connected to and capable of communication with converter 202 via communication path 116. In the embodiment of FIG. 2B, LCD 114 is included as a component of module 108 and is connected to and capable of communication with converter 202 via internal communication path 118 (e.g., a shared bus or discrete connections). LCD 114 can also be capable of receiving signals from, and transmitting signals to, energy buffer 204 and/or energy source 206 over paths 116 or 118.

Module 108 can also include monitor circuitry 208 configured to monitor (e.g., collect, sense, measure, and/or determine) one or more aspects of module 108 and/or the components thereof, such as voltage, current, temperature or other operating parameters that constitute status information (or can be used to determine status information by, e.g., LCD 114). A main function of the status information is to describe the state of the one or more energy sources 206 of the module 108 to enable determinations as to how much to utilize the energy source in comparison to other sources in system 100, although status information describing the state of other components (e.g., voltage, temperature, and/or presence of a fault in buffer 204, temperature and/or presence of a fault in converter 202, presence of a fault elsewhere in module 108, etc.) can be used in the utilization determination as well. Monitor circuitry 208 can include one or more sensors, shunts, dividers, fault detectors, Coulomb counters, controllers or other hardware and/or software configured to monitor such aspects. Monitor circuitry 208 can be separate from the various components 202, 204, and 206, or can be integrated with each component 202, 204, and 206 (as shown in FIGS. 2A-2B), or any combination thereof. In some embodiments, monitor circuitry 208 can be part of or shared with a Battery Management System (BMS) for a battery energy source 204. Discrete circuitry is not needed to monitor each type of status information, as more than one type of status information can be monitored with a single circuit or device, or otherwise algorithmically determined without the need for additional circuits.

LCD 114 can receive status information (or raw data) about the module components over communication paths 116, 118. LCD 114 can also transmit information to module components over paths 116, 118. Paths 116 and 118 can include diagnostics, measurement, protection, and control signal lines. The transmitted information can be control signals for one or more module components. The control signals can be switch signals for converter 202 and/or one or more signals that request the status information from module components. For example, LCD 114 can cause the status information to be transmitted over paths 116, 118 by requesting the status information directly, or by applying a stimulus (e.g., voltage) to cause the status information to be generated, in some cases in combination with switch signals that place converter 202 in a particular state.

The physical configuration or layout of module 108 can take various forms. In some embodiments, module 108 can include a common housing in which all module components, e.g., converter 202, buffer 204, and source 206, are housed, along with other optional components such as an integrated LCD 114. In other embodiments, the various components can be separated in discrete housings that are secured together. FIG. 2C is a block diagram depicting an example embodiment of a module 108 having a first housing 220 that holds an energy source 206 of the module and accompanying electronics such as monitor circuitry, a second housing 222 that holds module electronics such as converter 202, energy buffer 204, and other accompany electronics such as monitor circuitry, and a third housing 224 that holds LCD 114 (not shown) for the module 108. In alternative embodiments the module electronics and LCD 114 can be housed within the same single housing. In still other embodiments, the module electronics, LCD 114, and energy source(s) can be housed within the same single housing for the module 108. Electrical connections between the various module components can proceed through the housings 220, 222, 224 and can be exposed on any of the housing exteriors for connection with other devices such as other modules 108 or MCD 112.

Modules 108 of system 100 can be physically arranged with respect to each other in various configurations that depend on the needs of the application and the number of loads. For example, in a stationary application where system 100 provides power for a microgrid, modules 108 can be placed in one or more racks or other frameworks. Such configurations may be suitable for larger mobile applications as well, such as maritime vessels. Alternatively, modules 108 can be secured together and located within a common housing, referred to as a pack. A rack or a pack may have its own dedicated cooling system shared across all modules. Pack configurations are useful for smaller mobile applications such as electric cars. System 100 can be implemented with one or more racks (e.g., for parallel supply to a microgrid) or one or more packs (e.g., serving different motors of the vehicle), or combination thereof. FIG. 2D is a block diagram depicting an example embodiment of system 100 configured as a pack with nine modules 108 electrically and physically coupled together within a common housing 230.

Examples of these and further configurations are described in Int'l. Appl. No. PCT/US20/25366, filed Mar. 27, 2020 and titled Module-Based Energy Systems Capable of Cascaded and Interconnected Configurations, and Methods Related Thereto, which is incorporated by reference herein in its entirety for all purposes.

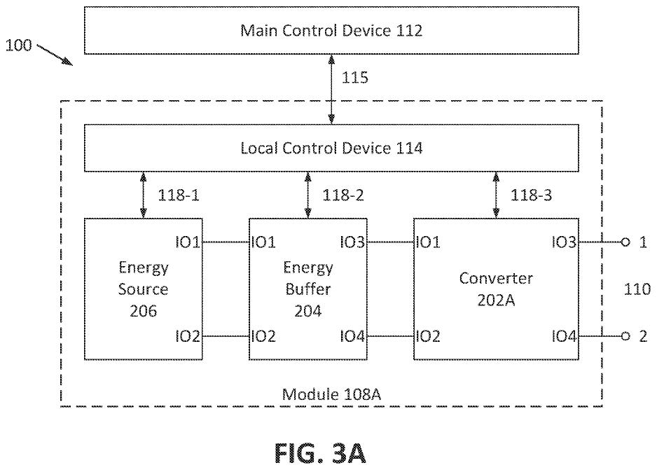

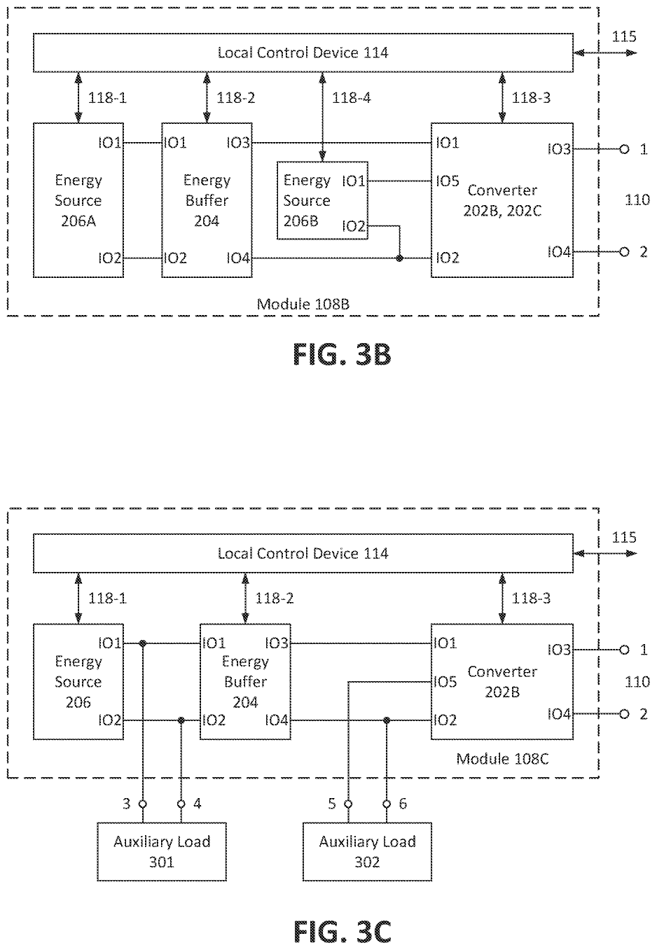

FIGS. 3A-3C are block diagrams depicting example embodiments of modules 108 having various electrical configurations. These embodiments are described as having one LCD 114 per module 108, with the LCD 114 housed within the associated module, but can be configured otherwise as described herein. FIG. 3A depicts a first example configuration of a module 108A within system 100. Module 108A includes energy source 206, energy buffer 204, and converter 202A. Each component has power connection ports (e.g., terminals, connectors) into which power can be input and/or from which power can be output, referred to herein as IO ports. Such ports can also be referred to as input ports or output ports depending on the context.

Energy source 206 can be configured as any of the energy source types described herein (e.g., a battery as described with respect to FIGS. 4A-4D, an HED capacitor, a fuel cell, or otherwise). Ports IO1 and 102 of energy source 206 can be connected to ports IO1 and IO2, respectively, of energy buffer 204. Energy buffer 204 can be configured to buffer or filter high and low frequency energy pulsations arriving at buffer 204 through converter 202, which can otherwise degrade the performance of module 108. The topology and components for buffer 204 are selected to accommodate the maximum permissible amplitude of these high frequency voltage pulsations. Several (non-exhaustive) example embodiments of energy buffer 204 are depicted in the schematic diagrams of FIGS. 5A-5C. In FIG. 5A, buffer 204 is an electrolytic and/or film capacitor C_{EB}, in FIG. 5B buffer 204 is a Z-source network 710, formed by two inductors L_{EB1} and L_{EB2} and two electrolytic and/or film capacitors C_{EB1} and C_{EB2}, and in FIG. 5C buffer 204 is a quasi Z-source network 720, formed by two inductors L_{EB1} and L_{EB2}, two electrolytic and/or film capacitors C_{EB1} and C_{EB2} and a diode D_{EB}.

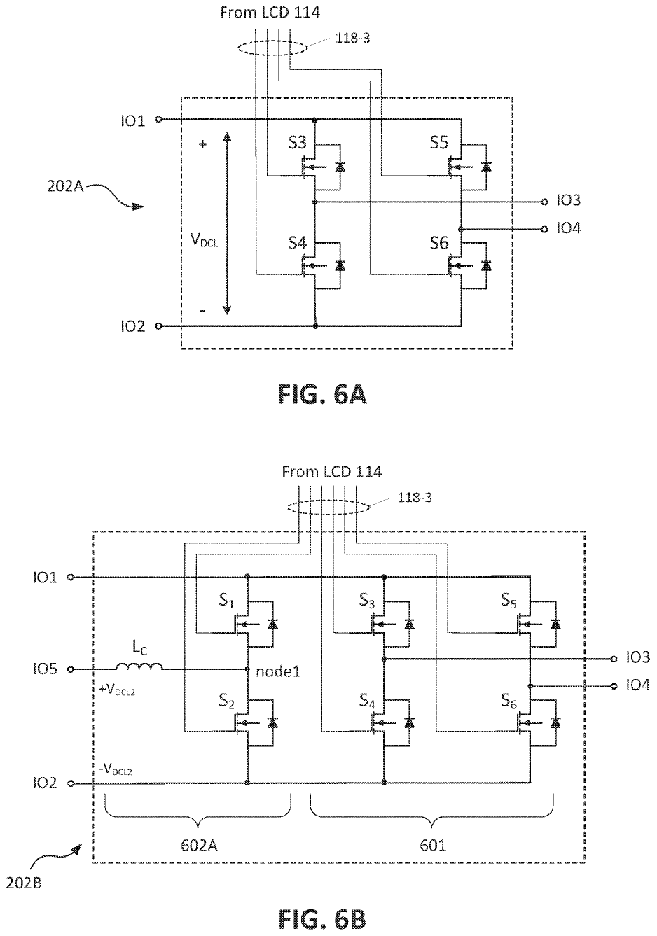

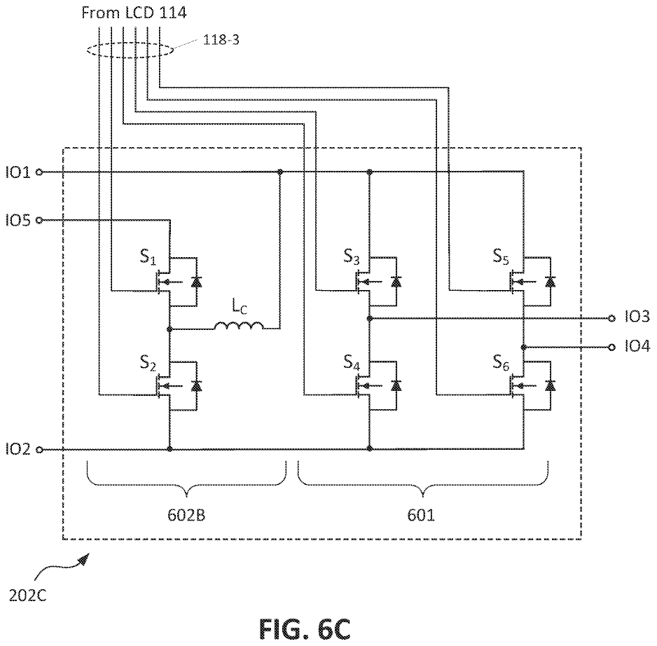

Ports IO3 and IO4 of energy buffer 204 can be connected to ports IO1 and IO2, respectively, of converter 202A, which can be configured as any of the power converter types described herein. FIG. 6A is a schematic diagram depicting an example embodiment of converter 202A configured as a DC-AC converter that can receive a DC voltage at ports IO1 and IO2 and switch to generate pulses at ports IO3 and IO4. Converter 202A can include multiple switches, and here converter 202A includes four switches S3, S4, S5, S6 arranged in a full bridge configuration. Control system 102 or LCD 114 can independently control each switch via control input lines 118-3 to each gate.

The switches can be any suitable switch type, such as power semiconductors like the metal-oxide-semiconductor field-effect transistors (MOSFETs) shown here, insulated gate bipolar transistors (IGBTs), or gallium nitride (GaN) transistors. Semiconductor switches can operate at relatively high switching frequencies, thereby permitting converter 202 to be operated in pulse-width modulated (PWM) mode if desired, and to respond to control commands within a relatively short interval of time. This can provide a high tolerance of output voltage regulation and fast dynamic behavior in transient modes.

In this embodiment, a DC line voltage V_{DCL} can be applied to converter 202 between ports IO1 and 102. By connecting V_{DCL} to ports IO3 and 104 by different combinations of switches S3, S4, S5, S6, converter 202 can generate three different voltage outputs at ports IO3 and IO4: +V_{DCL}, 0, and −V_{DCL}. A switch signal provided to each switch controls whether the switch is on (closed) or off (open). To obtain +V_{DCL}, switches S3 and S6 are turned on while S4 and S5 are turned off, whereas −V_{DCL} can be obtained by turning on switches S4 and S5 and turning off S3 and S6. The output voltage can be set to zero (including near zero) or a reference voltage by turning on S3 and S5 with S4 and S6 off, or by turning on S4 and S6 with S3 and S5 off. These voltages can be output from module 108 over power connection 110. Ports IO3 and IO4 of converter 202 can be connected to (or form) module IO ports 1 and 2 of power connection 110, so as to generate the output voltage for use with output voltages from other modules 108.

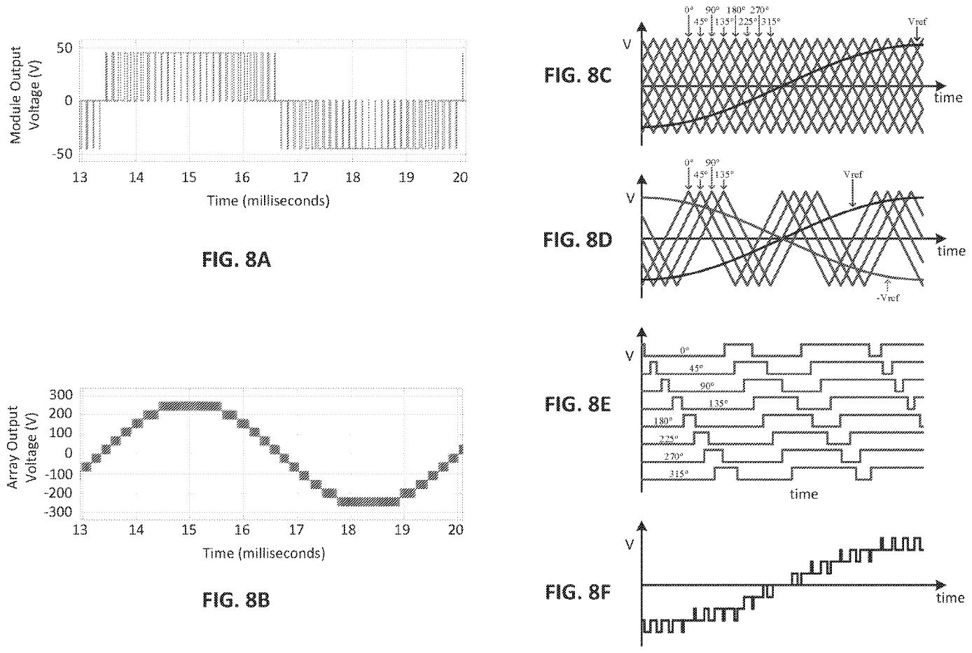

The control or switch signals for the embodiments of converter 202 described herein can be generated in different ways depending on the control technique utilized by system 100 to generate the output voltage of converter 202. In some embodiments, the control technique is a PWM technique such as space vector pulse-width modulation (SVPWM) or sinusoidal pulse-width modulation (SPWM), or variations thereof. FIG. 8A is a graph of voltage versus time depicting an example of an output voltage waveform 802 of converter 202. For ease of description, the embodiments herein will be described in the context of a PWM control technique, although the embodiments are not limited to such. Other classes of techniques can be used. One alternative class is based on hysteresis, examples of which are described in Int'l Publ. Nos. WO 2018/231810A1, WO 2018/232403A1, and WO 2019/183553A1, which are incorporated by reference herein for all purposes.

Each module 108 can be configured with multiple energy sources 206 (e.g., two, three, four, or more). Each energy source 206 of module 108 can be controllable (switchable) to supply power to connection 110 (or receive power from a charge source) independent of the other sources 206 of the module. For example, all sources 206 can output power to connection 110 (or be charged) at the same time, or only one (or a subset) of sources 206 can supply power (or be charged) at any one time. In some embodiments, the sources 206 of the module can exchange energy between them, e.g., one source 206 can charge another source 206. Each of the sources 206 can be configured as any energy source described herein (e.g., battery, HED capacitor, fuel cell). Each of the sources 206 can be the same class (e.g., each can be a battery, each can be an HED capacitor, or each can be a fuel cell), or a different class (e.g., a first source can be a battery and a second source can be an HED capacitor or fuel cell, or a first source can be an HED capacitor and a second source can be a fuel cell).

FIG. 3B is a block diagram depicting an example embodiment of a module 108B in a dual energy source configuration with a primary energy source 206A and secondary energy source 206B. Ports IO1 and IO2 of primary source 202A can be connected to ports IO1 and IO2 of energy buffer 204. Module 108B includes a converter 202B having an additional IO port. Ports IO3 and IO4 of buffer 204 can be connected ports IO1 and IO2, respectively, of converter 202B. Ports IO1 and 102 of secondary source 206B can be connected to ports IO5 and IO2, respectively, of converter 202B (also connected to port IO4 of buffer 204).

In this example embodiment of module 108B, primary energy source 202A, along with the other modules 108 of system 100, supplies the average power needed by the load. Secondary source 202B can serve the function of assisting energy source 202 by providing additional power at load power peaks, or absorbing excess power, or otherwise.

As mentioned both primary source 206A and secondary source 206B can be utilized simultaneously or at separate times depending on the switch state of converter 202B. If at the same time, an electrolytic and/or a film capacitor (C_{ES}) can be placed in parallel with source 206B as depicted in FIG. 4E to act as an energy buffer for the source 206B, or energy source 206B can be configured to utilize an HED capacitor in parallel with another energy source (e.g., a battery or fuel cell) as depicted in FIG. 4F.

FIGS. 6B and 6C are schematic views depicting example embodiments of converters 202B and 202C, respectively. Converter 202B includes switch circuitry portions 601 and 602A. Portion 601 includes switches S3 through S6 configured as a full bridge in similar manner to converter 202A, and is configured to selectively couple IO1 and IO2 to either of IO3 and IO4, thereby changing the output voltages of module 108B. Portion 602A includes switches S1 and S2 configured as a half bridge and coupled between ports IO1 and IO2. A coupling inductor L_{C} is connected between port IO5 and a node1 present between switches S1 and S2 such that switch portion 602A is a bidirectional converter that can regulate (boost or buck) voltage (or inversely current). Switch portion 602A can generate two different voltages at node1, which are +V_{DCL2} and 0, referenced to port IO2, which can be at virtual zero potential. The current drawn from or input to energy source 202B can be controlled by regulating the voltage on coupling inductor L_{C}, using, for example, a pulse-width modulation technique or a hysteresis control method for commutating switches S1 and S2. Other techniques can also be used.

Converter 202C differs from that of 202B as switch portion 602B includes switches S1 and S2 configured as a half bridge and coupled between ports IO5 and IO2. A coupling inductor L_{C} is connected between port IO1 and a node1 present between switches S1 and S2 such that switch portion 602B is configured to regulate voltage.

Control system 102 or LCD 114 can independently control each switch of converters 202B and 202C via control input lines 118-3 to each gate. In these embodiments and that of FIG. 6A, LCD 114 (not MCD 112) generates the switching signals for the converter switches. Alternatively, MCD 112 can generate the switching signals, which can be communicated directly to the switches, or relayed by LCD 114. In some embodiments, driver circuitry for generating the switching signals can be present in or associated with MCD 112 and/or LCD 114.

The aforementioned zero voltage configuration for converter 202 (turning on S3 and S5 with S4 and S6 off, or turning on S4 and S6 with S3 and S5 off) can also be referred to as a bypass state for the given module. This bypass state can be entered if a fault is detected in the given module, or if a system fault is detected warranting shut-off of more than one (or all modules) in an array or system. A fault in the module can be detected by LCD 114 and the control switching signals for converter 202 can be set to engage the bypass state without intervention by MCD 112. Alternatively, fault information for a given module can be communicated by LCD 114 to MCD 112, and MCD 112 can then make a determination whether to engage the bypass state, and if so, can communicate instructions to engage the bypass state to the LCD 114 associated with the module having the fault, at which point LCD 114 can output switching signals to cause engagement of the bypass state.

In embodiments where a module 108 includes three or more energy sources 206, converters 202B and 202C can be scaled accordingly such that each additional energy source 206B is coupled to an additional IO port leading to an additional switch circuitry portion 602A or 602B, depending on the needs of the particular source. For example a dual source converter 202 can include both switch portions 202A and 202B.

Modules 108 with multiple energy sources 206 are capable of performing additional functions such as energy sharing between sources 206, energy capture from within the application (e.g., regenerative braking), charging of the primary source by the secondary source even while the overall system is in a state of discharge, and active filtering of the module output. The active filtering function can also be performed by modules having a typical electrolytic capacitor instead of a secondary energy source. Examples of these functions are described in more detail in Int'l. Appl. No. PCT/US20/25366, filed Mar. 27, 2020 and titled Module-Based Energy Systems Capable of Cascaded and Interconnected Configurations, and Methods Related Thereto, and Int′1. Publ. No. WO 2019/183553, filed Mar. 22, 2019, and titled Systems and Methods for Power Management and Control, both of which are incorporated by reference herein in their entireties for all purposes.

Each module 108 can be configured to supply one or more auxiliary loads with its one or more energy sources 206. Auxiliary loads are loads that require lower voltages than the primary load 101. Examples of auxiliary loads can be, for example, an on-board electrical network of an electric vehicle, or an HVAC system of an electric vehicle. The load of system 100 can be, for example, one of the phases of the electric vehicle motor or electrical grid. This embodiment can allow a complete decoupling between the electrical characteristics (terminal voltage and current) of the energy source and those of the loads.

FIG. 3C is a block diagram depicting an example embodiment of a module 108C configured to supply power to a first auxiliary load 301 and a second auxiliary load 302, where module 108C includes an energy source 206, energy buffer 204, and converter 202B coupled together in a manner similar to that of FIG. 3B. First auxiliary load 301 requires a voltage equivalent to that supplied from source 206. Load 301 is coupled to IO ports 3 and 4 of module 108C, which are in turn coupled to ports IO1 and 102 of source 206. Source 206 can output power to both power connection 110 and load 301. Second auxiliary load 302 requires a constant voltage lower than that of source 206. Load 302 is coupled to IO ports 5 and 6 of module 108C, which are coupled to ports IO5 and IO2, respectively, of converter 202B. Converter 202B can include switch portion 602 having coupling inductor L_{C} coupled to port IO5 (FIG. 6B). Energy supplied by source 206 can be supplied to load 302 through switch portion 602 of converter 202B. It is assumed that load 302 has an input capacitor (a capacitor can be added to module 108C if not), so switches S1 and S2 can be commutated to regulate the voltage on and current through coupling inductor L_{C} and thus produce a stable constant voltage for load 302. This regulation can step down the voltage of source 206 to the lower magnitude voltage is required by load 302.

Module 108C can thus be configured to supply one or more first auxiliary loads in the manner described with respect to load 301, with the one or more first loads coupled to IO ports 3 and 4. Module 108C can also be configured to supply one or more second auxiliary loads in the manner described with respect to load 302. If multiple second auxiliary loads 302 are present, then for each additional load 302 module 108C can be scaled with additional dedicated module output ports (like 5 and 6), an additional dedicated switch portion 602, and an additional converter IO port coupled to the additional portion 602.

Energy source 206 can thus supply power for any number of auxiliary loads (e.g., 301 and 302), as well as the corresponding portion of system output power needed by primary load 101. Power flow from source 206 to the various loads can be adjusted as desired.

Module 108 can be configured as needed with two or more energy sources 206 (FIG. 3B) and to supply first and/or second auxiliary loads (FIG. 3C) through the addition of a switch portion 602 and converter port 105 for each additional source 206B or second auxiliary load 302. Additional module IO ports (e.g., 3, 4, 5, 6) can be added as needed. Module 108 can also be configured as an interconnection module to exchange energy (e.g., for balancing) between two or more arrays, two or more packs, or two or more systems 100 as described further herein. This interconnection functionality can likewise be combined with multiple source and/or multiple auxiliary load supply capabilities.

Control system 102 can perform various functions with respect to the components of modules 108A, 108B, and 108C. These functions can include management of the utilization (amount of use) of each energy source 206, protection of energy buffer 204 from over-current, over-voltage and high temperature conditions, and control and protection of converter 202.

For example, to manage (e.g., adjust by increasing, decreasing, or maintaining) utilization of each energy source 206, LCD 114 can receive one or more monitored voltages, temperatures, and currents from each energy source 206 (or monitor circuitry). The monitored voltages can be at least one of, preferably all, voltages of each elementary component independent of the other components (e.g., each individual battery cell, HED capacitor, and/or fuel cell) of the source 206, or the voltages of groups of elementary components as a whole (e.g., voltage of the battery array, HED capacitor array, and/or fuel cell array). Similarly the monitored temperatures and currents can be at least one of, preferably all, temperatures and currents of each elementary component independent of the other components of the source 206, or the temperatures and currents of groups of elementary components as a whole, or any combination thereof. The monitored signals can be status information, with which LCD 114 can perform one or more of the following: calculation or determination of a real capacity, actual State of Charge (SOC) and/or State of Health (SOH) of the elementary components or groups of elementary components; set or output a warning or alarm indication based on monitored and/or calculated status information; and/or transmission of the status information to MCD 112. LCD 114 can receive control information (e.g., a modulation index, synchronization signal) from MCD 112 and use this control information to generate switch signals for converter 202 that manage the utilization of the source 206.

To protect energy buffer 204, LCD 114 can receive one or more monitored voltages, temperatures, and currents from energy buffer 204 (or monitor circuitry). The monitored voltages can be at least one of, preferably all, voltages of each elementary component of buffer 204 (e.g., of C_{EB}, C_{EB1}, C_{EB2}, L_{EB1}, L_{EB2}, D_{EB}) independent of the other components, or the voltages of groups of elementary components or buffer 204 as a whole (e.g., between IO1 and IO2 or between IO3 and IO4). Similarly the monitored temperatures and currents can be at least one of, preferably all, temperatures and currents of each elementary component of buffer 204 independent of the other components, or the temperatures and currents of groups of elementary components or of buffer 204 as a whole, or any combination thereof. The monitored signals can be status information, with which LCD 114 can perform one or more of the following: set or output a warning or alarm indication; communicate the status information to MCD 112; or control converter 202 to adjust (increase or decrease) the utilization of source 206 and module 108 as a whole for buffer protection.

To control and protect converter 202, LCD 114 can receive the control information from MCD 112 (e.g., a modulated reference signal, or a reference signal and a modulation index), which can be used with a PWM technique in LCD 114 to generate the control signals for each switch (e.g., S1 through S6). LCD 114 can receive a current feedback signal from a current sensor of converter 202, which can be used for overcurrent protection together with one or more fault status signals from driver circuits (not shown) of the converter switches, which can carry information about fault statuses (e.g., short circuit or open circuit failure modes) of all switches of converter 202. Based on this data, LCD 114 can make a decision on which combination of switching signals to be applied to manage utilization of module 108, and potentially bypass or disconnect converter 202 (and the entire module 108) from system 100.

If controlling a module 108C that supplies a second auxiliary load 302, LCD 114 can receive one or more monitored voltages (e.g., the voltage between IO ports 5 and 6) and one or more monitored currents (e.g., the current in coupling inductor L_{C}, which is a current of load 302) in module 108C. Based on these signals, LCD 114 can adjust the switching cycles (e.g., by adjustment of modulation index or reference waveform) of S1 and S2 to control (and stabilize) the voltage for load 302.

### Cascaded Energy System Topology Examples

Two or more modules 108 can be coupled together in a cascaded array that outputs a voltage signal formed by a superposition of the discrete voltages generated by each module 108 within the array. FIG. 7A is a block diagram depicting an example embodiment of a topology for system 100 where N modules 108-1, 108-2 . . . 108-N are coupled together in series to form a serial array 700. In this and all embodiments described herein, N can be any integer greater than one. Array 700 includes a first system IO port SIO1 and a second system IO port SIO2 across which is generated an array output voltage. Array 700 can be used as a DC or single phase AC energy source for DC or AC single-phase loads, which can be connected to SIO1 and SIO2 of array 700. FIG. 8A is a plot of voltage versus time depicting an example output signal produced by a single module 108 having a 48 volt energy source. FIG. 8B is a plot of voltage versus time depicting an example single phase AC output signal generated by array 700 having six 48V modules 108 coupled in series.

System 100 can be arranged in a broad variety of different topologies to meet varying needs of the applications. System 100 can provide multi-phase power (e.g., two-phase, three-phase, four-phase, five-phase, six-phase, etc.) to a load by use of multiple arrays 700, where each array can generate an AC output signal having a different phase angle.

FIG. 7B is a block diagram depicting system 100 with two arrays 700-PA and 700-PB coupled together. Each array 700 is one-dimensional, formed by a series connection of N modules 108. The two arrays 700-PA and 700-PB can each generate a single-phase AC signal, where the two AC signals have different phase angles PA and PB (e.g., 180 degrees apart). IO port 1 of module 108-1 of each array 700-PA and 700-PB can form or be connected to system IO ports SIO1 and SIO2, respectively, which in turn can serve as a first output of each array that can provide two phase power to a load (not shown). Or alternatively ports SIO1 and SIO2 can be connected to provide single phase power from two parallel arrays. IO port 2 of module 108-N of each array 700-PA and 700-PB can serve as a second output for each array 700-PA and 700-PB on the opposite end of the array from system IO ports SIO1 and SIO2, and can be coupled together at a common node and optionally used for an additional system IO port SIO3 if desired, which can serve as a neutral. This common node can be referred to as a rail, and IO port 2 of modules 108-N of each array 700 can be referred to as being on the rail side of the arrays.

FIG. 7C is a block diagram depicting system 100 with three arrays 700-PA, 700-PB, and 700-PC coupled together. Each array 700 is one-dimensional, formed by a series connection of N modules 108. The three arrays 700-1 and 700-2 can each generate a single-phase AC signal, where the three AC signals have different phase angles PA, PB, PC (e.g., 120 degrees apart). IO port 1 of module 108-1 of each array 700-PA, 700-PB, and 700-PC can form or be connected to system IO ports SIO1, SIO2, and SIO3, respectively, which in turn can provide three phase power to a load (not shown). IO port 2 of module 108-N of each array 700-PA, 700-PB, and 700-PC can be coupled together at a common node and optionally used for an additional system IO port SIO4 if desired, which can serve as a neutral.

The concepts described with respect to the two-phase and three-phase embodiments of FIGS. 7B and 7C can be extended to systems 100 generating still more phases of power. For example, a non-exhaustive list of additional examples includes: system 100 having four arrays 700, each of which is configured to generate a single phase AC signal having a different phase angle (e.g., 90 degrees apart): system 100 having five arrays 700, each of which is configured to generate a single phase AC signal having a different phase angle (e.g., 72 degrees apart); and system 100 having six arrays 700, each array configured to generate a single phase AC signal having a different phase angle (e.g., 60 degrees apart).

System 100 can be configured such that arrays 700 are interconnected at electrical nodes between modules 108 within each array. FIG. 7D is a block diagram depicting system 100 with three arrays 700-PA, 700-PB, and 700-PC coupled together in a combined series and delta arrangement. Each array 700 includes a first series connection of M modules 108, where M is two or greater, coupled with a second series connection of N modules 108, where Nis two or greater. The delta configuration is formed by the interconnections between arrays, which can be placed in any desired location. In this embodiment, IO port 2 of module 108-(M+N) of array 700-PC is coupled with IO port 2 of module 108-M and IO port 1 of module 108-(M+1) of array 700-PA, IO port 2 of module 108-(M+N) of array 700-PB is coupled with IO port 2 of module 108-M and IO port 1 of module 108-(M+1) of array 700-PC, and IO port 2 of module 108-(M+N) of array 700-PA is coupled with IO port 2 of module 108-M and IO port 1 of module 108-(M+1) of array 700-PB.

FIG. 7E is a block diagram depicting system 100 with three arrays 700-PA, 700-PB, and 700-PC coupled together in a combined series and delta arrangement. This embodiment is similar to that of FIG. 7D except with different cross connections. In this embodiment, IO port 2 of module 108-M of array 700-PC is coupled with IO port 1 of module 108-1 of array 700-PA, IO port 2 of module 108-M of array 700-PB is coupled with IO port 1 of module 108-1 of array 700-PC, and IO port 2 of module 108-M of array 700-PA is coupled with IO port 1 of module 108-1 of array 700-PB. The arrangements of FIGS. 7D and 7E can be implemented with as little as two modules in each array 700. Combined delta and series configurations enable an effective exchange of energy between all modules 108 of the system (interphase balancing) and phases of power grid or load, and also allows reducing the total number of modules 108 in an array 700 to obtain the desired output voltages.

In the embodiments described herein, although it is advantageous for the number of modules 108 to be the same in each array 700 within system 100, such is not required and different arrays 700 can have differing numbers of modules 108. Further, each array 700 can have modules 108 that are all of the same configuration (e.g., all modules are 108A, all modules are 108B, all modules are 108C, or others) or different configurations (e.g., one or more modules are 108A, one or more are 108B, and one or more are 108C, or otherwise). As such, the scope of topologies of system 100 covered herein is broad.

### Control Methodology Examples

As mentioned, control of system 100 can be performed according to various methodologies, such as hysteresis or PWM. Several examples of PWM include space vector modulation and sine pulse width modulation, where the switching signals for converter 202 are generated with a phase shifted carrier technique that continuously rotates utilization of each module 108 to equally distribute power among them.

FIGS. 8C-8F are plots depicting an example embodiment of a phase-shifted PWM control methodology that can generate a multilevel output PWM waveform using incrementally shifted two-level waveforms. An X-level PWM waveform can be created by the summation of (X−1)/2 two-level PWM waveforms. These two-level waveforms can be generated by comparing a reference waveform Vref to carriers incrementally shifted by 360°/(X−1). The carriers are triangular, but the embodiments are not limited to such. A nine-level example is shown in FIG. 8C (using four modules 108). The carriers are incrementally shifted by 360°/(9−1)=45° and compared to Vref. The resulting two-level PWM waveforms are shown in FIG. 8E. These two-level waveforms may be used as the switching signals for semiconductor switches (e.g., S1 though S6) of converters 202. As an example with reference to FIG. 8E, for a one-dimensional array 700 including four modules 108 each with a converter 202, the 0° signal is for control of S3 and the 180° signal for S6 of the first module 108-1, the 45° signal is for S3 and the 225° signal for S6 of the second module 108-2, the 90 signal is for S3 and the 270 signal is for S6 of the third module 108-3, and the 135 signal is for S3 and the 315 signal is for S6 of the fourth module 108-4. The signal for S3 is complementary to S4 and the signal for S5 is complementary to S6 with sufficient dead-time to avoid shoot through of each half-bridge. FIG. 8F depicts an example single phase AC waveform produced by superposition (summation) of output voltages from the four modules 108.

An alternative is to utilize both a positive and a negative reference signal with the first (N−1)/2 carriers. A nine-level example is shown in FIG. 8D. In this example, the 0° to 135° switching signals (FIG. 8E) are generated by comparing +Vref to the 0° to 135° carriers of FIG. 8D and the 180° to 315° switching signals are generated by comparing −Vref to the 0° to 135° carriers of FIG. 8D. However, the logic of the comparison in the latter case is reversed. Other techniques such as a state machine decoder may also be used to generate gate signals for the switches of converter 202.

In multi-phase system embodiments, the same carriers can be used for each phase, or the set of carriers can be shifted as a whole for each phase. For example, in a three phase system with a single reference voltage (Vref), each array 700 can use the same number of carriers with the same relative offsets as shown in FIGS. 8C and 8D, but the carriers of the second phase are shift by 120 degrees as compared to the carriers of the first phase, and the carriers of the third phase are shifted by 240 degrees as compared to the carriers of the first phase. If a different reference voltage is available for each phase, then the phase information can be carried in the reference voltage and the same carriers can be used for each phase. In many cases the carrier frequencies will be fixed, but in some example embodiments, the carrier frequencies can be adjusted, which can help to reduce losses in EV motors under high current conditions.

The appropriate switching signals can be provided to each module by control system 102. For example, MCD 112 can provide Vref and the appropriate carrier signals to each LCD 114 depending upon the module or modules 108 that LCD 114 controls, and the LCD 114 can then generate the switching signals. Or all LCDs 114 in an array can be provided with all carrier signals and the LCD can select the appropriate carrier signals.

The relative utilizations of each module 108 can adjusted based on status information to perform balancing or of one or more parameters as described herein. Balancing of parameters can involve adjusting utilization to minimize parameter divergence over time as compared to a system where individual module utilization adjustment is not performed. The utilization can be the relative amount of time a module 108 is discharging when system 100 is in a discharge state, or the relative amount of time a module 108 is charging when system 100 is in a charge state.

As described herein, modules 108 can be balanced with respect to other modules in an array 700, which can be referred to as intra array or intraphase balancing, and different arrays 700 can be balanced with respect to each other, which can be referred to as interarray or interphase balancing. Arrays 700 of different subsystems can also be balanced with respect to each other. Control system 102 can simultaneously perform any combination of intraphase balancing, interphase balancing, utilization of multiple energy sources within a module, active filtering, and auxiliary load supply.

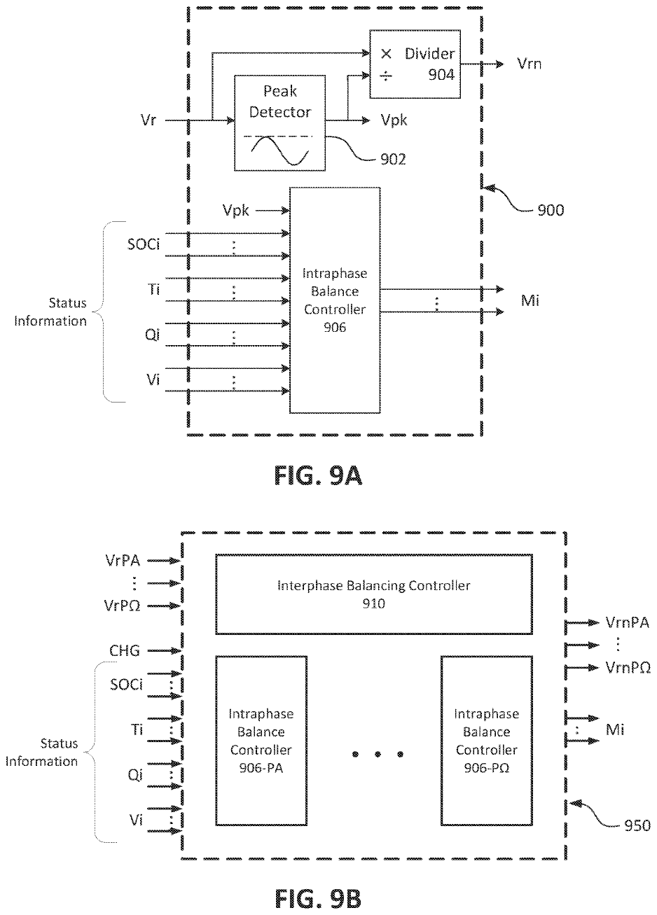

FIG. 9A is a block diagram depicting an example embodiment of an array controller 900 of control system 102 for a single-phase AC or DC array. Array controller 900 can include a peak detector 902, a divider 904, and an intraphase (or intra array) balance controller 906. Array controller 900 can receive a reference voltage waveform (Vr) and status information about each of the N modules 108 in the array (e.g., state of charge (SOCi), temperature (Ti), capacity (Qi), and voltage (Vi)) as inputs, and generate a normalized reference voltage waveform (Vrn) and modulation indexes (Mi) as outputs. Peak detector 902 detects the peak (Vpk) of Vr, which can be specific to the phase that controller 900 is operating with and/or balancing. Divider 904 generates Vrn by dividing Vr by its detected Vpk. Intraphase balance controller 906 uses Vpk along with the status information (e.g., SOCi, Ti, Qi, Vi, etc.) to generate modulation indexes Mi for each module 108 within the array 700 being controlled.

The modulation indexes and Vrn can be used to generate the switching signals for each converter 202. The modulation index can be a number between zero and one (inclusive of zero and one). For a particular module 108, the normalized reference Vrn can be modulated or scaled by Mi, and this modulated reference signal (Vrnm) can be used as Vref (or −Vref) according to the PWM technique described with respect to FIGS. 8C-8F, or according to other techniques. In this manner, the modulation index can be used to control the PWM switching signals provided to the converter switching circuitry (e.g., S3-S6 or S1-S6), and thus regulate the operation of each module 108. For example, a module 108 being controlled to maintain normal or full operation may receive an Mi of one, while a module 108 being controlled to less than normal or full operation may receive an Mi less than one, and a module 108 controlled to cease power output may receive an Mi of zero. This operation can be performed in various ways by control system 102, such as by MCD 112 outputting Vrn and Mi to the appropriate LCDs 114 for modulation and switch signal generation, by MCD 112 performing modulation and outputting the modulated Vrnm to the appropriate LCDs 114 for switch signal generation, or by MCD 112 performing modulation and switch signal generation and outputting the switch signals to the LCDs or the converters 202 of each module 108 directly. Vrn can be sent continually with Mi sent at regular intervals, such as once for every period of the Vrn, or one per minute, etc.

Controller 906 can generate an Mi for each module 108 using any type or combination of types of status information (e.g., SOC, temperature (T), Q, SOH, voltage, current) described herein. For example, when using SOC and T, a module 108 can have a relatively high Mi if SOC is relatively high and temperature is relatively low as compared to other modules 108 in array 700. If either SOC is relatively low or T is relatively high, then that module 108 can have a relatively low Mi, resulting in less utilization than other modules 108 in array 700. Controller 906 can determine Mi such that the sum of module voltages does not exceed Vpk. For example, Vpk can be the sum of the products of the voltage of each module's source 206 and Mi for that module (e.g., Vpk=M₁V₁+M₂V₂+M₃V₃ . . . +M_{N}V_{N}, etc). A different combination of modulation indexes, and thus respective voltage contributions by the modules, may be used but the total generated voltage should remain the same.

Controller 900 can control operation, to the extent it does not prevent achieving the power output requirements of the system at any one time (e.g., such as during maximum acceleration of an EV), such that SOC of the energy source(s) in each module 108 remains balanced or converges to a balanced condition if they are unbalanced, and/or such that temperature of the energy source(s) or other component (e.g., energy buffer) in each module remains balanced or converges to a balanced condition if they are unbalanced. Power flow in and out of the modules can be regulated such that a capacity difference between sources does not cause an SOC deviation. Balancing of SOC and temperature can indirectly cause some balancing of SOH. Voltage and current can be directly balanced if desired, but in many embodiments the main goal of the system is to balance SOC and temperature, and balancing of SOC can lead to balance of voltage and current in a highly symmetric systems where modules are of similar capacity and impedance.

Since balancing all parameters may not be possible at the same time (e.g., balancing of one parameter may further unbalance another parameter), a combination of balancing any two or more parameters (SOC, T, Q, SOH, V, I) may be applied with priority given to either one depending on the requirements of the application. Priority in balancing can be given to SOC over other parameters (T, Q, SOH, V, I), with exceptions made if one of the other parameters (T, Q, SOH, V, I) reaches a severe unbalanced condition outside a threshold.

Balancing between arrays 700 of different phases (or arrays of the same phase, e.g., if parallel arrays are used) can be performed concurrently with intraphase balancing. FIG. 9B depicts an example embodiment of an Ω-phase (or Ω-array) controller 950 configured for operation in an Ω-phase system 100, having at least Ω arrays 700, where Ω is any integer greater than one. Controller 950 can include one interphase (or interarray) controller 910 and Ω intraphase balance controllers 906-PA . . . 906-PΩ for phases PA through PΩ, as well as peak detector 902 and divider 904 (FIG. 9A) for generating normalized references VrnPA through VrnPΩ from each phase-specific reference VrPA through VrPΩ. Intraphase controllers 906 can generate Mi for each module 108 of each array 700 as described with respect to FIG. 9A. Interphase balance controller 910 is configured or programmed to balance aspects of modules 108 across the entire multi-dimensional system, for example, between arrays of different phases. This may be achieved through injecting common mode to the phases (e.g., neutral point shifting) or through the use of interconnection modules (described herein) or through both. Common mode injection involves introducing a phase and amplitude shift to the reference signals VrPA through VrPΩ to generate normalized waveforms VrnPA through VrnPΩ to compensate for unbalance in one or more arrays, and is described further in Int′l. Appl. No. PCT/US20/25366 incorporated herein.

Controllers 900 and 950 (as well as balance controllers 906 and 910) can be implemented in hardware, software or a combination thereof within control system 102. Controllers 900 and 950 can be implemented within MCD 112, distributed partially or fully among LCDs 114, or may be implemented as discrete controllers independent of MCD 112 and LCDs 114.

### Interconnection (IC) Module Examples

Modules 108 can be connected between the modules of different arrays 700 for the purposes of exchanging energy between the arrays, acting as a source for an auxiliary load, or both. Such modules are referred to herein as interconnection (IC) modules 108IC. IC module 108IC can be implemented in any of the already described module configurations (108A, 108B, 108C) and others to be described herein. IC modules 108IC can include any number of one or more energy sources, an optional energy buffer, switch circuitry for supplying energy to one or more arrays and/or for supplying power to one or more auxiliary loads, control circuitry (e.g., a local control device), and monitor circuitry for collecting status information about the IC module itself or its various loads (e.g., SOC of an energy source, temperature of an energy source or energy buffer, capacity of an energy source, SOH of an energy source, voltage and/or current measurements pertaining to the IC module, voltage and/or current measurements pertaining to the auxiliary load(s), etc.).

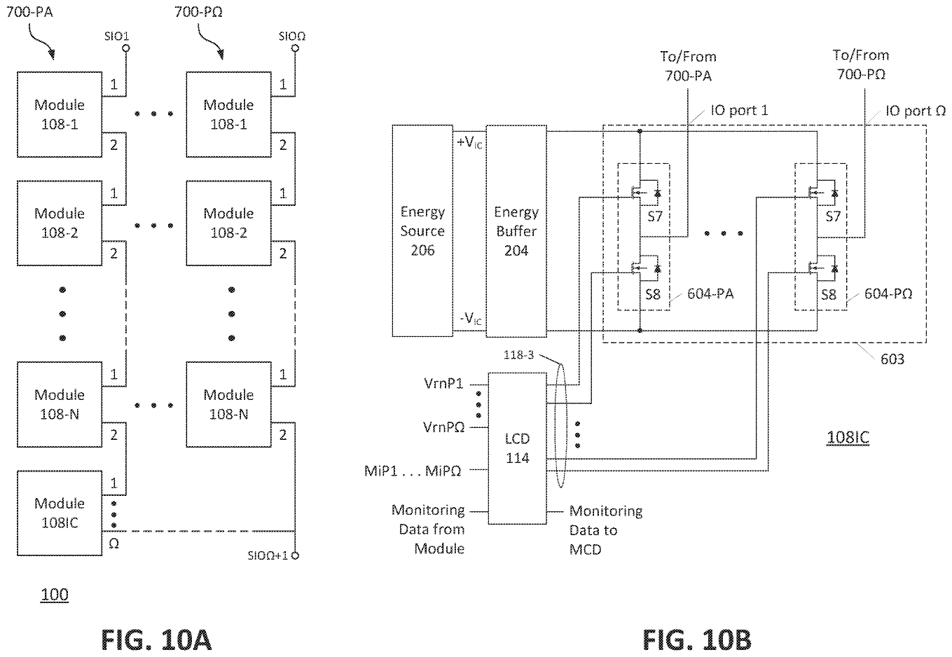

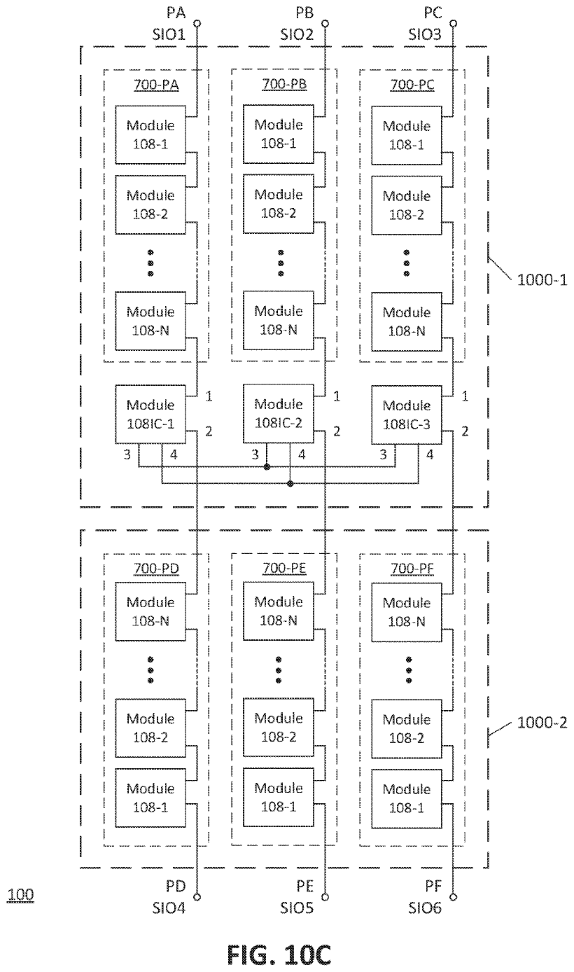

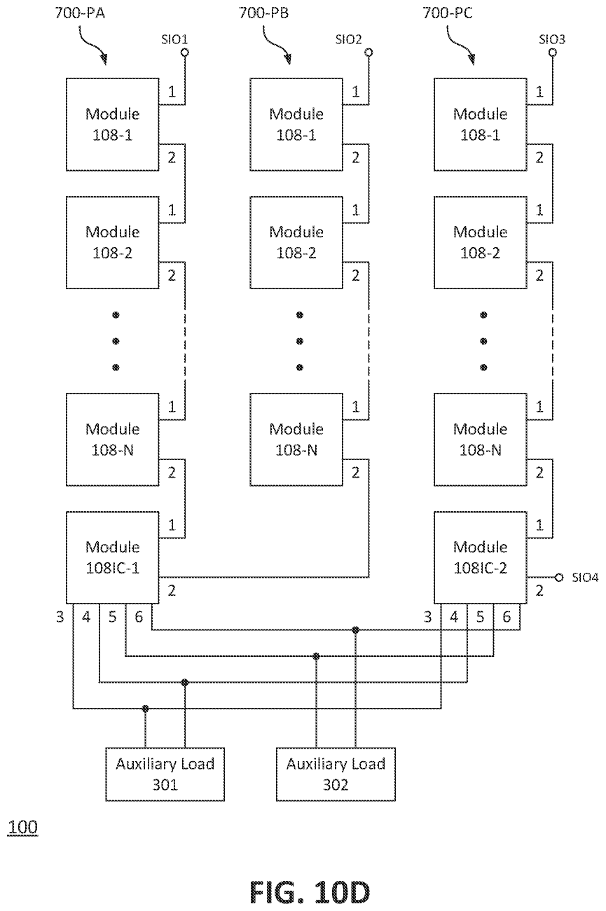

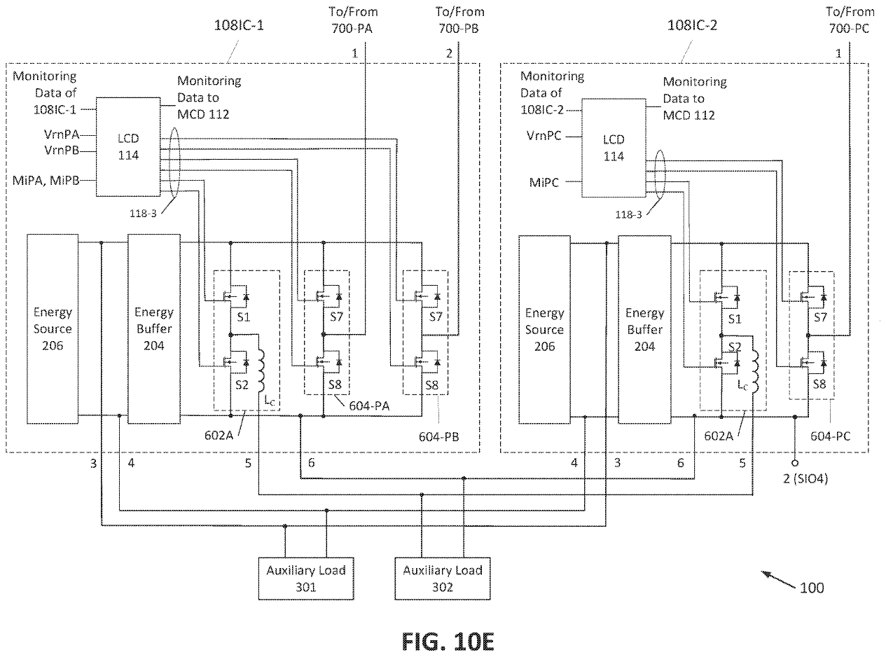

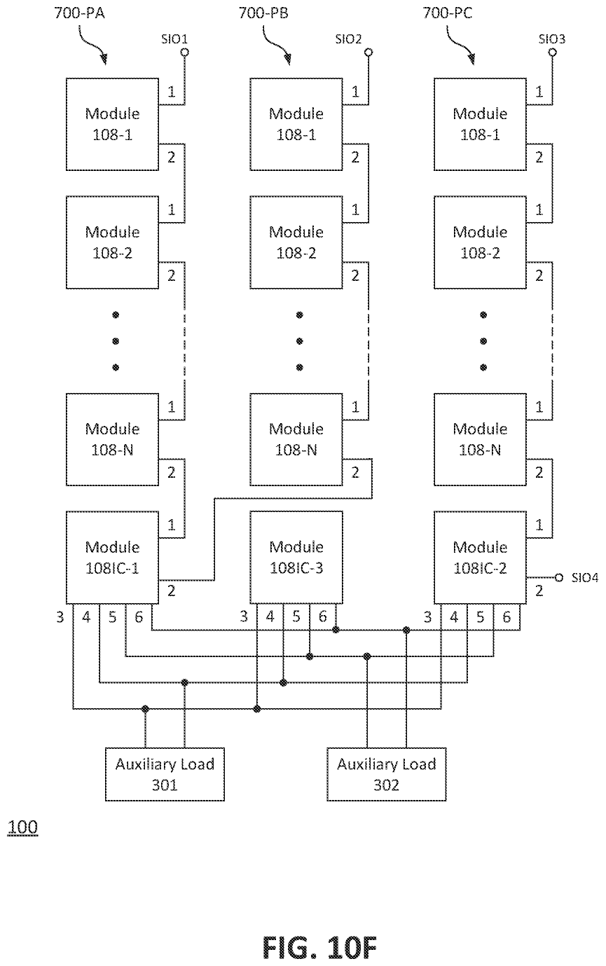

FIG. 10A is a block diagram depicting an example embodiment of a system 100 capable of producing Ω-phase power with Ω arrays 700-PA through 700-PΩ, where Ω can be any integer greater than one. In this and other embodiments, IC module 108IC can be located on the rail side of arrays 700 such the arrays 700 to which module 108IC are connected (arrays 700-PA through 700-PΩ in this embodiment) are electrically connected between module 108IC and outputs (e.g., SIO1 through SIOΩ) to the load. Here, module 108IC has Ω IO ports for connection to IO port 2 of each module 108-N of arrays 700-PA through 700-PΩ. In the configuration depicted here, module 108IC can perform interphase balancing by selectively connecting the one or more energy sources of module 108IC to one or more of the arrays 700-PA through 700-PΩ (or to no output, or equally to all outputs, if interphase balancing is not required). System 100 can be controlled by control system 102 (not shown, see FIG. 1A).

FIG. 10B is a schematic diagram depicting an example embodiment of module 108IC. In this embodiment module 108IC includes an energy source 206 connected with energy buffer 204 that in turn is connected with switch circuitry 603. Switch circuitry 603 can include switch circuitry units 604-PA through 604-PΩ for independently connecting energy source 206 to each of arrays 700-PA through 700-PΩ, respectively. Various switch configurations can be used for each unit 604, which in this embodiment is configured as a half-bridge with two semiconductor switches S7 and S8. Each half bridge is controlled by control lines 118-3 from LCD 114. This configuration is similar to module 108A described with respect to FIG. 3A. As described with respect to converter 202, switch circuitry 603 can be configured in any arrangement and with any switch types (e.g., MOSFET, IGBT, Silicon, GaN, etc.) suitable for the requirements of the application.

Switch circuitry units 604 are coupled between positive and negative terminals of energy source 206 and have an output that is connected to an IO port of module 108IC. Units 604-PA through 604-PΩ can be controlled by control system 102 to selectively couple voltage +V_{IC} or −V_{IC} to the respective module I/O ports 1 through Ω. Control system 102 can control switch circuitry 603 according to any desired control technique, including the PWM and hysteresis techniques mentioned herein. Here, control circuitry 102 is implemented as LCD 114 and MCD 112 (not shown). LCD 114 can receive monitoring data or status information from monitor circuitry of module 108IC. This monitoring data and/or other status information derived from this monitoring data can be output to MCD 112 for use in system control as described herein. LCD 114 can also receive timing information (not shown) for purposes of synchronization of modules 108 of the system 100 and one or more carrier signals (not shown), such as the sawtooth signals used in PWM (FIGS. 8C-8D).

For interphase balancing, proportionally more energy from source 206 can be supplied to any one or more of arrays 700-PA through 700-PΩ2 that is relatively low on charge as compared to other arrays 700. Supply of this supplemental energy to a particular array 700 allows the energy output of those cascaded modules 108-1 thru 108-N in that array 700 to be reduced relative to the unsupplied phase array(s).

For example, in some example embodiments applying PWM, LCD 114 can be configured to receive the normalized voltage reference signal (Vrn) (from MCD 112) for each of the one or more arrays 700 that module 108IC is coupled to, e.g., VrnPA through VrnPΩ. LCD 114 can also receive modulation indexes MiPA through MiPΩ for the switch units 604-PA through 604-PΩ for each array 700, respectively, from MCD 112. LCD 114 can modulate (e.g., multiply) each respective Vrn with the modulation index for the switch section coupled directly to that array (e.g., VrnA multiplied by MiA) and then utilize a carrier signal to generate the control signal(s) for each switch unit 604. In other embodiments, MCD 112 can perform the modulation and output modulated voltage reference waveforms for each unit 604 directly to LCD 114 of module 108IC. In still other embodiments, all processing and modulation can occur by a single control entity that can output the control signals directly to each unit 604.

This switching can be modulated such that power from energy source 206 is supplied to the array(s) 700 at appropriate intervals and durations. Such methodology can be implemented in various ways.

Based on the collected status information for system 100, such as the present capacity (Q) and SOC of each energy source in each array, MCD 112 can determine an aggregate charge for each array 700 (e.g., aggregate charge for an array can be determined as the sum of capacity times SOC for each module of that array). MCD 112 can determine whether a balanced or unbalanced condition exists (e.g., through the use of relative difference thresholds and other metrics described herein) and generate modulation indexes MiPA through MiPΩ accordingly for each switch unit 604-PA through 604-PΩ.

During balanced operation, Mi for each switch unit 604 can be set at a value that causes the same or similar amount of net energy over time to be supplied by energy source 206 and/or energy buffer 204 to each array 700. For example, Mi for each switch unit 604 could be the same or similar, and can be set at a level or value that causes the module 108IC to perform a net or time average discharge of energy to the one or more arrays 700-PA through 700-PΩ during balanced operation, so as to drain module 108IC at the same rate as other modules 108 in system 100. In some embodiments, Mi for each unit 604 can be set at a level or value that does not cause a net or time average discharge of energy during balanced operation (causes a net energy discharge of zero). This can be useful if module 108IC has a lower aggregate charge than other modules in the system.

When an unbalanced condition occurs between arrays 700, then the modulation indexes of system 100 can be adjusted to cause convergence towards a balanced condition or to minimize further divergence. For example, control system 102 can cause module 108IC to discharge more to the array 700 with low charge than the others, and can also cause modules 108-1 through 108-N of that low array 700 to discharge relatively less (e.g., on a time average basis). The relative net energy contributed by module 108IC increases as compared to the modules 108-1 through 108-N of the array 700 being assisted, and also as compared to the amount of net energy module 108IC contributes to the other arrays. This can be accomplished by increasing Mi for the switch unit 604 supplying that low array 700, and by decreasing the modulation indexes of modules 108-1 through 108-N of the low array 700 in a manner that maintains Vout for that low array at the appropriate or required levels, and maintaining the modulation indexes for other switch units 604 supplying the other higher arrays relatively unchanged (or decreasing them).

The configuration of module 108IC in FIGS. 10A-10B can be used alone to provide interphase or interarray balancing for a single system, or can be used in combination with one or more other modules 108IC each having an energy source and one or more switch portions 604 coupled to one or more arrays. For example, a module 108IC with Ω switch portions 604 coupled with Ω different arrays 700 can be combined with a second module 108IC having one switch portion 604 coupled with one array 700 such that the two modules combine to service a system 100 having Ω+1 arrays 700. Any number of modules 108IC can be combined in this fashion, each coupled with one or more arrays 700 of system 100.

Furthermore, IC modules can be configured to exchange energy between two or more subsystems of system 100. FIG. 10C is a block diagram depicting an example embodiment of system 100 with a first subsystem 1000-1 and a second subsystem 1000-2 interconnected by IC modules. Specifically, subsystem 1000-1 is configured to supply three-phase power, PA, PB, and PC, to a first load (not shown) by way of system I/O ports SIO1, SIO2, and SIO3, while subsystem 1000-2 is configured to supply three-phase power PD, PE, and PF to a second load (not shown) by way of system I/O ports SIO4, SIO5, and SIO06, respectively. For example, subsystems 1000-1 and 1000-2 can be configured as different packs supplying power for different motors of an EV or as different racks supplying power for different microgrids.

In this embodiment each module 108IC is coupled with a first array of subsystem 1000-1 (via IO port 1) and a first array of subsystem 1000-2 (via IO port 2), and each module 108IC can be electrically connected with each other module 108IC by way of I/O ports 3 and 4, which are coupled with the energy source 206 of each module 108IC as described with respect to module 108C of FIG. 3C. This connection places sources 206 of modules 108IC-1, 108IC-2, and 108IC-3 in parallel, and thus the energy stored and supplied by modules 108IC is pooled together by this parallel arrangement. Other arrangements such as serious connections can also be used. Modules 108IC are housed within a common enclosure of subsystem 1000-1, however the interconnection modules can be external to the common enclosure and physically located as independent entities between the common enclosures of both subsystems 1000.

Each module 108IC has a switch unit 604-1 coupled with IO port 1 and a switch unit 604-2 coupled with I/O port 2, as described with respect to FIG. 10B. Thus, for balancing between subsystems 1000 (e.g., inter-pack or inter-rack balancing), a particular module 108IC can supply relatively more energy to either or both of the two arrays to which it is connected (e.g., module 108IC-1 can supply to array 700-PA and/or array 700-PD). The control circuitry can monitor relative parameters (e.g., SOC and temperature) of the arrays of the different subsystems and adjust the energy output of the IC modules to compensate for imbalances between arrays or phases of different subsystems in the same manner described herein as compensating for imbalances between two arrays of the same rack or pack. Because all three modules 108IC are in parallel, energy can be efficiently exchanged between any and all arrays of system 100. In this embodiment, each module 108IC supplies two arrays 700, but other configurations can be used including a single IC module for all arrays of system 100 and a configuration with one dedicated IC module for each array 700 (e.g., six IC modules for six arrays, where each IC module has one switch unit 604). In all cases with multiple IC modules, the energy sources can be coupled together in parallel so as to share energy as described herein.

In systems with IC modules between phases, interphase balancing can also be performed by neutral point shifting (or common mode injection) as described above. Such a combination allows for more robust and flexible balancing under a wider range of operating conditions. System 100 can determine the appropriate circumstances under which to perform interphase balancing with neutral point shifting alone, interphase energy injection alone, or a combination of both simultaneously.

IC modules can also be configured to supply power to one or more auxiliary loads 301 (at the same voltage as source 206) and/or one or more auxiliary loads 302 (at voltages stepped down from source 302). FIG. 10D is a block diagram depicting an example embodiment of a three-phase system 100A with two modules 108IC connected to perform interphase balancing and to supply auxiliary loads 301 and 302. FIG. 10E is a schematic diagram depicting this example embodiment of system 100 with emphasis on modules 108IC-1 ad 108IC-2. Here, control circuitry 102 is again implemented as LCD 114 and MCD 112 (not shown). The LCDs 114 can receive monitoring data from modules 108IC (e.g., SOC of ES1, temperature of ES1, Q of ES1, voltage of auxiliary loads 301 and 302, etc.) and can output this and/or other monitoring data to MCD 112 for use in system control as described herein. Each module 108IC can include a switch portion 602A (or 602B described with respect to FIG. 6C) for each load 302 being supplied by that module, and each switch portion 602 can be controlled to maintain the requisite voltage level for load 302 by LCD 114 either independently or based on control input from MCD 112. In this embodiment, each module 108IC includes a switch portion 602A connected together to supply the one load 302, although such is not required.

FIG. 10F is a block diagram depicting another example embodiment of a three-phase system configured to supply power to one or more auxiliary loads 301 and 302 with modules 108IC-1, 108IC-2, and 108IC-3. In this embodiment, modules 108IC-1 and 108IC-2 are configured in the same manner as described with respect to FIGS. 10D-10E. Module 108IC-3 is configured in a purely auxiliary role and does not actively inject voltage or current into any array 700 of system 100. In this embodiment, module 108IC-3 can be configured like module 108C of FIG. 3B, having a converter 202B,C (FIGS. 6B-6C) with one or more auxiliary switch portions 602A, but omitting switch portion 601. As such, the one or more energy sources 206 of module 108IC-3 are interconnected in parallel with those of modules 108IC-1 and 108IC-2, and thus this embodiment of system 100 is configured with additional energy for supplying auxiliary loads 301 and 302, and for maintaining charge on the sources 206A of modules 108IC-1 and 108IC-2 through the parallel connection with the source 206 of module 108IC-3.

The energy source 206 of each IC module can be at the same voltage and capacity as the sources 206 of the other modules 108-1 through 108-N of the system, although such is not required. For example, a relatively higher capacity can be desirable in an embodiment where one module 108IC applies energy to multiple arrays 700 (FIG. 10A) to allow the IC module to discharge at the same rate as the modules of the phase arrays themselves. If the module 108IC is also supplying an auxiliary load, then an even greater capacity may be desired so as to permit the IC module to both supply the auxiliary load and discharge at relatively the same rate as the other modules.

### Second Life Energy Source Examples

Energy sources 206 described herein can be used in systems 100 described herein in both first life and second life applications. A first life of a source 206 is an original application in which source 206 is used. For example, the first life application is the first implementation in which sources 206 are put to use by the first customer of sources 206 after their original manufacture (and not refurbishment). The user of sources 206 in their first life will typically have received sources 206 from the manufacturer, distributor, or original equipment manufacturer (OEM). Batteries 206 used in a first life application will typically have the same electrochemistry (e.g., will have the same variant of lithium ion electrochemistry (e.g., LFP, NMC)) and will have the same nominal voltage and will have a capacity variation across the pack or system that is minimal (e.g., 5% or less). Use of an energy storage system with batteries 206 in their first life application will result in batteries 206 having a longer lifespan in that first life application, and upon removal from that first life application, the batteries 206 will be more similar in terms of capacity degradation than batteries from a first life application not using the energy storage system.

As used herein, a “second life” application refers to any application or implementation after the first life application (e.g., a second implementation, third implementation, fourth implementation, etc.) of source 206. A second life energy source refers to any energy source (e.g., battery or HED capacitor) implemented in that source's second life application.

An example of a first life application for batteries 206 is within an energy storage system for an EV. Then, at the end of that life (e.g., after 100,000 miles of driving, or after degradation of the batteries within that battery pack by a threshold amount), the batteries 206 can be removed from the battery pack, optionally subjected to refurbishing and testing, and then implemented in a second life application that can be, e.g., used within a stationary energy storage system (e.g., residential, commercial, or industrial energy buffering, EV charging station energy buffering, renewable source (e.g., wind, solar, hydroelectric), energy buffering, and the like) or another mobile energy storage system (e.g., battery pack for an electric car, bus, train, or truck). Similarly, the first life application can be a first stationary application and the second life application can be a stationary or mobile application.

For the second life application, sources 206 can be selected and/or utilized by system 100 to minimize (or at least reduce) any differences in initial capacity and nominal voltage. For example, sources 206 having a capacity difference of 5% or more can be included within system 100 and operated to provide energy for a load. In another example, an operator or automated system can select sources 206 for system 100 that have a capacity difference within a threshold amount, e.g., to reduce the initial capacity differences between sources of system 206. If modules 108 are compatible with both the first and second life application (e.g., with or without reconfiguration), modules 108 can be selected for the second life application based on the capacity difference of sources 206 of modules 108.

System 100 can adjust utilization of each source 206 individually such that sources 206 within system 100 or packs of system 100 are relatively balanced in terms of SOC or total charge (SOC times capacity) as the pack or system 100 is discharged, even though the sources 206 in system 100 can have widely varying capacities. Similarly, system 100 can maintain balance as the pack or system 100 is charged. Sources 206 can vary not only in terms of capacity but also in nominal voltage, power rating, electrochemical type (e.g., a combination of LFP and NMC batteries) and the like. Thus, system 100 can be used such that all modules 206 within system 100 or each pack of system 100 are second life energy sources (or such that a combination of first life and second life energy sources are used), having various combinations of different characteristics.

In one example, system 100 can include second life energy sources 206 (and optionally one or more first life energy sources 206) having energy capacity variations of 2% or more, 5% or more, 10% or more, 15% or more, 20% or more, or 25% or more, 30% or more, 5-30%, 10-30%, and/or 20-30%.

In another example, system 100 can include second energy life sources 206 (and optionally one or more first life energy sources 206) having energy capacity per mass density variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having peak power per mass density variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having nominal voltage variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having operating voltage range variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having maximum specified current rise time variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having specified peak current variations of 2% or more, 5% or more, 10% or more, 15% or more, 20% or more, or 25% or more, 30% or more, 5-30%, 10-30%, and/or 20-30%.

A variation of X % (e.g., 5% or more, or 5 to 30%) can be met by a variation between the module 108 having the highest value for that parameter and the module 108 having the lowest value for that parameter within system 100. For example, a variation of 5% or more in capacity can be met by a system 100 where the module 108 with the lowest capacity source 206 has a capacity that is 95% or less than that of the module 108 with the highest capacity source 206. For each and every embodiment and parameter disclosed herein, the time at which the system 100 having one or more second life sources satisfies the X % variation condition in that parameter can be at installation of the system 100, at commissioning of the system 100, after replacement of one source 206 with another source 206, after operation of system 100 for 10 hours or more, after operation of system 100 for 100 hours or more, after operation of system 100 for 1000 hours or more, and/or after operation of system 100 for 10,000 hours or more. For example, a variation of capacity of 5% or more can occur after system 100 is operated for 1000 hours, even though the variation in capacity was not present at the time of commissioning. This reflects the capability of the embodiments of system 100 to continue to operate with and account for capacity differences between sources 206 that grow over time of operation.

In another example, system 100 can include second life energy sources 206 (and optionally one or more first life energy sources 206) having variations of electrochemical type (e.g., lithium ion batteries with non-lithium ion batteries, or different lithium ion batteries (e.g., any combination of NMC, LFP, LTO, or other lithium ion battery types).

System 100 can include second life energy sources 206 (and optionally one or more first life energy sources 206) having any combination of the characteristics provides in the preceding examples.

### Examples of Monitoring SOC Using Multiple Integrator Circuits

System 100 described herein can include integrator circuits configured to monitor current into an energy source 206 and out of energy source 206, e.g., to estimate the SOC of energy source 206. If the current of energy source 206 is not accurately monitored, SOC estimations that are based on the monitored current will also be inaccurate, which may result in operational inefficiencies, degradation of energy source 206, reduced lifetime of energy source 206, and so on.

The embodiments will be described primarily in the context of energy sources 206 that are batteries, although the embodiments are applicable to other energy source types as well (e.g., high energy density capacitors and fuel cells). The embodiments can be used to monitor current into and out of battery packs, individual batteries, individual battery cells, and/or other arrangements of batteries and other energy sources 206.

While not required to be used with any particular configuration of an energy storage system 100, the embodiments of system 100 described herein can particularly benefit from use with the present SOC monitoring embodiments. When used with the embodiments of system 100, control system 102 can use more accurate SOC estimates for energy sources 206 of modules 108 to more efficiently operate modules 108, e.g., to more accurately balance the SOC of modules 108.

FIG. 11A is a block diagram depicting an example embodiment of a SOC monitor device 1100. In general, the SOC monitor device 1100 is configured to monitor current into and out of a battery 206. SOC monitor device 1100 can also be configured to estimate the SOC of battery 206 based on the monitored current and optionally additional signals, e.g., voltage measurements that represent the voltage level of battery 206 and/or temperature measurements that represent the temperature of battery 206. SOC monitor device 1100 can estimate the SOC of energy source 206 based on the signals, e.g., using an SOC estimation model 1122 as described below.

The SOC monitor device 1100 can be implemented as a separate device. For example, when implemented in an embodiment of system 100, SOC monitor device 1100 can be implemented as a separate device, e.g., separate from MCD 112, LCD 114, and/or a BMS for battery 206. In such examples, SOC monitor device 1100 can be configured to monitor current into and out of battery 206, which can also be referred to as current of battery 206, and provide data indicating the monitored current to LCD 114 for use by either LCD 114, MCD 112, or another device in estimating the SOC of battery 206. In another example, SOC monitor device 1100 can be configured to estimate the SOC of battery 206 based on the current of battery 206 and provide data indicating the SOC to LCD 114 and/or MCD 112. In other examples, functionality of SOC monitor device 1100 can be distributed between MCD 112, LCD 114, and/or a BMS for battery 206.

SOC monitor device 1100 includes a multi-integrator circuit 1103 and an SOC measurement control device (SMCD) 1130. Multi-integrator circuit 1103 is configured to generate integrated voltage values that represent (e.g., that are proportional to) the charge drawn from or supplied to energy source 206. Multi-integrator circuit 1103 includes switches 1105 and 1120 and multiple integrator circuits 1110. In these embodiments, any number of two or more parallel integrator circuits 1110 can be used (e.g., N is greater than or equal to two).

Switch 1105 is configured to selectively pass current measurement signals (Iₛₑₙₛₑ) for battery 206 to an integrator circuit 1110, e.g., to one of the N integrator circuits 1110. In this example embodiment, switch 1105 is coupled to monitor circuitry 208 of energy source 206 to receive the current measurement signals. For example, switch 1105 can be electrically coupled via path 1141 to a current sensing element of monitor circuitry 208 that is configured to sense the current into and out of energy source 206. The current measurement signals can be in the form of a voltage level that represents the measured current level.

Switch 1105 can selectively route current measurement signals to integrator circuits 1110 based on a control signal received from SMCD 1130 over communication path or link 1140-1. Switch 1105 can be a single pole multiple throw switch that includes an input and multiple outputs, e.g., one output for each integrator circuit 1110. For example, if multi-integrator circuit 1103 includes two integrator circuits 1110, switch 1105 can be a single pole double throw (SPDT) switch. The input of switch 1105 is coupled to monitor circuitry 208 to receive current measurement signals and each output of switch 1105 is coupled to an integrator circuit 1110.

Switch 1120 is configured to selectively pass integrated voltage values for battery 206 from an integrator circuit 1110, e.g., from one of the N integrator circuits 1110, to SMCD 1130. Switch 1120 can selectively route an integrated voltage value from one of the integrator circuits 1110 to SMCD 1130 based on a control signal received from SMCD 1130 over communication path or link 1140-2. Switch 1120 can be a multiple pole single throw switch that includes multiple inputs, e.g., one input for each integrator circuit 1110, and an output. For example, if multi-integrator circuit 1103 includes two integrator circuits 1110, switch 1120 can be a double pole single throw (DPST) switch. Each input of switch 1120 is coupled to an integrator circuit 1110 and the output of switch 1120 is coupled to an input of SMCD 1130. Switches 1105 and 1120 can be any suitable type of switch having multiple inputs and/or multiple outputs.

Each integrator circuit 1110 is configured to integrate current measurement signals received from switch 1105 to generate an integrated voltage value. The integrated voltage value is proportional to the integral of the current measurement signals, e.g., the integral of the voltage levels representing the current measurements. An example integrator circuit is depicted in FIG. 11B and described in detail. In general, each integrator circuit 1110 includes an input for receiving current measurement signals and an output that outputs an integrated voltage value based on received current measurement signals, e.g., those that have been received since integrator circuit 1110 was last reset by SMCD 1130.

As current measurement signals are received, integrator circuit 1110 integrates the measurements over time to generate an integrated voltage value. The gradient of the output voltage of an integrator is proportional to the magnitude of the current measurement signal (and therefore the measured current level) at its input. The direction of the slope of the output voltage at any time is aligned with the current direction in the sensing element, and a horizontal line represents zero current flow.

In particular, the voltage on the output of integrator circuit 1110 is proportional to the charge drawn from or supplied to battery 206, as shown in Equation (1):

Q=I×t (1)

In Equation (1), Q is the amount of charge, I is the current level, and t is the duration of time that the current is at that level.

SMCD 1130 can operate switches 1105 and 1130 and integrator circuits 1110 such that one integrator circuit 1110 is actively integrating current measurements while each other integrator circuit 1110 is maintaining (e.g., storing) a previous integrated voltage value at its output. This provides time for SMCD 1130 to obtain the integrated voltage value from each integrator circuit 1110 that is not actively integrating without missing current measurements that would otherwise be missed due to cyclical holds for reporting the integrated voltage values.

SMCD 1130 can cycle between multiple states in which a different integrator circuit 1110 is actively integrating current measurements. For example, if multi-integrator circuit 1103 includes two integrator circuits 1110, SMCD 1130 can cycle between a first state in which integrator circuit 1110-1 actively integrates current measurements while integrator circuit 1110-N stores its integrated voltage value and a second state in which integrator circuit 1110-N actively integrates current measurements while integrator circuit 1110-1 stores its integrated voltage value. Generally, while SMCD 1130 operates switch 1105 to pass current to one integrator circuit 1110 to monitor the current, e.g., for a period of time, SMCD 1130 allows for the integrated voltage value from another integrator circuit 1110 to be read by SMCD 1130 during the period of time.

For example, in the first state, SMCD 1130 can send a control signal to switch 1105 over communication path or link 1140-1. This control signal can instruct switch 1105 to route current measurement signals received at the input of switch 1105 to integrator circuit 1110-1. This allows integrator circuit 1110-1 to integrate the current measurement signals and store the integrated voltage value at its output, which can change as measurement signals are received and integrated. SMCD 1130 can also send a control signal to switch 1120 over communication path or link 1140-2. This control signal can instruct switch 1120 to route the integrated voltage signal stored by integrator circuit 1110-N to SMCD 1130. As integrator circuit 1110-N is not actively integrating current measurements while in the first state, this integrated voltage signal remains constant while in the first state.

SMCD 1130 can switch from the first state to the second state, e.g., based on a toggle condition (described below). Prior to switching to the second state, SMCD 1130 can send a control signal to integrator circuit 1110-N over communication path or link 1140-3. This control signal can instruct integrator circuit 1110-N to reset its integrated voltage value to a specified value, e.g., to a value of zero, prior to integrating newly received current measurements.

In the second state, SMCD 1130 can send a control signal to switch 1105 over communication path or link 1140-1. This control signal can instruct switch 1105 to route current measurement signals received at the input of switch 1105 to integrator circuit 1110-N. This allows integrator circuit 1110-N to integrate the current measurement signals and store the integrated voltage value at its output. SMCD 1130 can also send a control signal to switch 1120 over communication path or link 1140-2. This control signal can instruct switch 1120 to route the integrated voltage value stored by integrator circuit 1110-1 to SMCD 1130. As integrator circuit 1110-1 is not actively integrating current measurements while in the second state, this integrated voltage signal remains constant while in the first state. In particular, this integrated voltage value is the result of integrating the current measurements while in the first state. Prior to transitioning from the second state back to the first state, SMCD 1130 can reset the integrated voltage value stored by integrator circuit 1110-1 by sending a control signal over communication path or link 1140-3.

SMCD 1130 can switch between states based on a toggle condition. In some embodiments, the toggle condition can be a specified duration of time. For example, SMCD 1130 can remain in each state for the specified duration of time before. The specified duration of time can be the same for each state or different for different states. The toggling time (e.g., the time that SMCD 1130 spends toggling between the two states) can be very small in comparison to the duration of time spent in each state.

In some embodiments, the toggle condition includes a voltage level trigger. The specified voltage level can be used to detect when a specified amount of charge has been removed or added to battery 206. In this example, SMCD 1130 can receive the integrated voltage value from the integrator circuit 1110 that is actively integrating the current measurements. While in the monitoring state, SMCD 1130 can compare received integrated voltage values to a voltage level trigger. The voltage level trigger can be a specified voltage level for triggering a transition to the next monitoring state. The voltage level trigger can be based on a specified amount of charge being added to or removed from battery 206. When the voltage level has changed by the specified amount, SMCD 1130 can transition between from the current state to the next state, e.g., from the first state in which integrator 1110-1 is actively integrating to the second state in which integrator 1110-N is actively integrating.

In some embodiments, SMCD 1130 can include a comparator for comparing the integrated voltage values to the voltage level trigger. In some embodiments, SOC monitor device 1100 can include a comparator (e.g., a comparator circuit) coupled between each integrator circuit 1110 and SMCD 1130. In this example, the comparator can compare the integrated voltage values to the voltage level trigger and output a state transition signal based on the comparison. For example, the comparator can output, to SMCD 1130, a positive or high level signal when the integrated voltage value meets or exceeds the voltage level trigger to initiate a state transition.

Using a voltage level to trigger transitions between states removes any fixed frequency aspect of a time based condition. An advantage of this approach is that the amount of charge represented by the integrated voltage value can be smaller than a time based approach, resulting in improved SOC monitoring accuracy. For example, using a voltage level to trigger the transitions can remove low current measurement issues that may be present due to the resolution of analog to digital converters (e.g., of SMCD 1130) that convert the integrated voltage values to digital signals for use in estimated SOC.

SMCD 1130 can store the integrated voltage values for each of multiple completed monitoring states and/or estimate the SOC of battery 206 based on the integrated voltage values of the multiple completed monitoring states. SMCD 1130 can estimate the SOC using the integrated voltage values and optionally additional signals, e.g., operating characteristics of battery 206 such as the voltage level of battery 206 and/or the temperature of battery 206. Monitoring circuitry 208 can provide data indicating these operating characteristics to SMCD 1130 over communication path or link 1142. For example, SMCD 1130 can provide signals including the integrated voltage values (or an aggregate integrated voltage value) as input to a SOC estimation model 1122 that is configured to output an estimated SOC based on the signals. SMCD 1130 can determine the aggregate integrated voltage value by summing integrated voltage values received from integrator circuits 1110-1 to 1110-N. In some embodiments, SOC estimation model 1122 is a trained machine learning model that is trained to estimate the SOC based on the input signals.

FIG. 11B is a schematic diagram depicting an example embodiment of an integrator circuit 1110. Each integrator circuit of SOC monitor device 1100 can be implemented using this embodiment of integrator circuit 1110. In this example, integrator circuit 1110 is an operational amplifier-based integrator circuit and includes an operational amplifier 1170, a reset switch 1145, capacitors 1150, resistors 1155, and filter circuit 1160. Other configurations of integrator circuits can also be used.

As described above, integrator circuit 1110 integrates current measurement signals, which can be in the form of input voltage signals. In particular, integrator circuit 1110 can output the integral of the current measurement signals (e.g., which can be in the form of input voltage signals that represent the current measurements) over a frequency range based on a time constant of integrator circuit 1110 and a bandwidth of operational amplifier 1170. The input voltage signal is applied to an inverting output so the output is inverted relative to a polarity of the input signal.

The capacitance of capacitors 1150 and the resistance of resistors 1155 are used to set the gain of integrator circuit 1110. This gain controls the rate at which the output voltage of operational amplifier 1170 increases and decreases based on current measurement signals Iₛₑₙₛₑ. The gain of integrator circuit 1110 and a toggling frequency between the monitoring states can be set such that a maximum current condition is satisfied at or near the end of a monitor state duration. The toggling frequency represents the rate at which SMCD 1130 switches between different monitoring states in which different integrator circuits 1110 integrate the current measurement signals Iₛₑₙₛₑ, and therefore the duration of time for each monitoring state. The gain of integrator circuit 1110 can be set such that the maximum current condition is satisfied (or is typically satisfied) at the completion of a monitor state. For example, the gain can be set using the values of capacitors 1150, resistors 1155, and the sense resistor such that the monitor state duration equals an average or median (or other measure of central tendency) duration of time taken for integrator circuit 1110 to integrate to the highest possible current value, e.g., such that the highest possible integrated voltage value is not reached during each occurrence of the monitor state.

For the example integrator circuit 1100 of FIG. 11B, the values of capacitors 1150 and resistors 1155 can be selected based on Equation (2):

$${V}_{out} = {V}_{ref} - \frac{1}{{R}_{2} {C}_{FB}} \int ( {I}_{mod} {R}_{sense} )$$

In Equation (2), Vₒᵤₜ is the output voltage of operational amplifier 1170, V_{ref} is the reference voltage for operational amplifier 1170, C_{FB} is the total capacitance of capacitors 1150, and I_{mod} is the actual current flowing through the sense resistor (Rₛₑₙₛₑ). For example, the current measurement signal Iₛₑₙₛₑ at the input of operational amplifier 1170 can be determined using Equation (3):

Iₛₑₙₛₑ=V_{ref}+I_{mod} Rₛₕᵤₙₜ (3)

Using Equation (2), the values of resistor R2, capacitors 1150, and the sense resistor can be selected to result in a target gain.

In some embodiments, the toggling frequency can based on parameters of integrator circuit 1110 and battery 206 being monitored. For example, the monitor state duration can be set such that, with a maximum current flow, integrator circuit 1110 will be in a linear operating range during the monitor state.

When integrator circuit 1110 is in a sensing state, integrator circuit 1100 is connected to a current sensing element to received current measurement signals. When integrator circuit 1100 is in a reporting state, integrator circuit 1110 is disconnected from the current sensing element. In either state, operational amplifier 1170 outputs the present integrated voltage value (Vᵢₙₜ), which can be routed to SMCD 1130 as described above.

An offset voltage V_{off} allows integrator circuit 1110 to monitor both positive and negative currents by offsetting the zero current condition for operational amplifier 1170. Filter circuit 1160 is configured to filter both high frequency noise of the current measurement signals Iₛₑₙₛₑ and to negate the effects of bias current.

Reset switch 1145 is configured to reset the output of operational amplifier 1170 in response to a control signal (e.g., reset signal), e.g., received from SMCD 1130. In this example, reset switch 1145 can be configured as a SPST switch of any suitable type, e.g., mechanical, semiconductor, etc. The reset signal can be configured to close switch 1145, which discharges capacitors 1150 and resets the output of operational amplifier 1170 to zero.

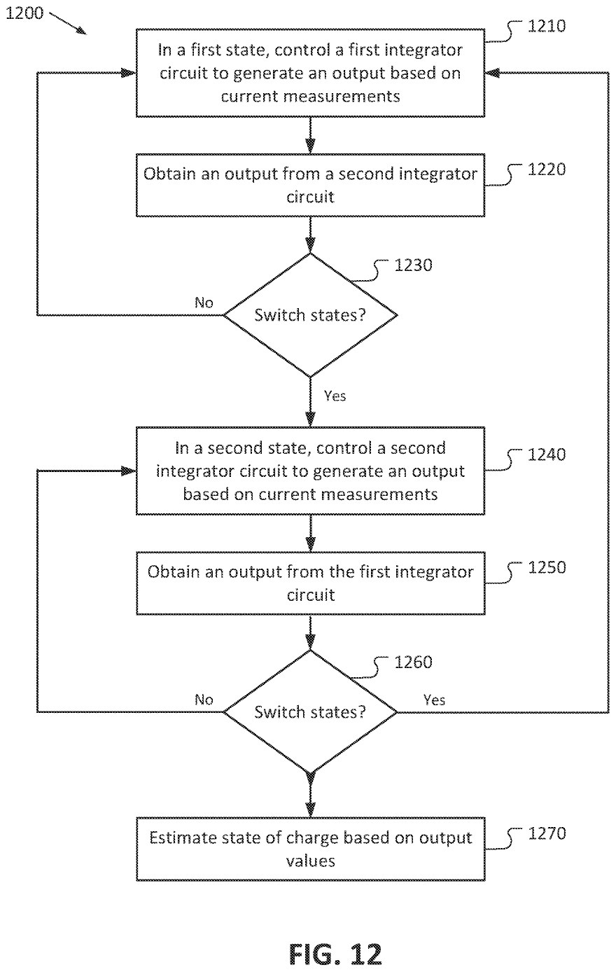

FIG. 12 is a flowchart depicting an example embodiment of a method 1200 of monitoring state of charge of an energy source 206. Method 1200 can be performed by SOC monitor device 1100 of FIG. 11A. SOC monitor device 1100 can cyclically perform operations of method 1200 over multiple time periods.

At step 1210, SOC monitor device 1100 operates in a first state. In the first state, SMCD 1130 controls a first integrator circuit 1110 of multiple parallel integrator circuits (e.g., of multi-integrator circuit 1103) to generate an output based on current measurement signals that represent current into or out of energy source 206. First integrator circuit 1110 can integrate the current measurement signals while in the first state to generate a first integrated voltage value. During the first state, each other integrator circuit 1110 of the multiple integrator circuits stores its integrated voltage value until SMCD 1130 switches to state in which that integrator circuit 1110 is the active integrator circuit that integrates the current measurement signals.

At step 1220, SOC monitor device 1100 obtains an output from a second integrator circuit 1110 of the multiple parallel integrator circuits. For example, the second integrator circuit can be configured to store a final second integrated voltage value from a previous iteration of a second state in which the second integrator circuit generated the second integrated voltage value.

At step 1230, SOC monitor device 1100 determines whether to switch (e.g., toggle) from the first state to the second state. SOC monitor device 1100 can determine whether to switch states based on one or more conditions. For example, SOC monitor device 1100 can be configured to switch states when the SOC monitor device 1100 has been in its current state for a specified period of time, as described above with reference to FIGS. 11A and 11B. In another example, SOC monitor device 1100 can be configured to switch states based on a voltage level trigger. In this example, SOC monitor device 1000 can be configured to monitor the integrated voltage value being output by the active integrator circuit 1110 (e.g., the first integrator circuit) while in the current state, which is the first state in this example. SOC monitor device 1100 can compare the integrated voltage value to a voltage level trigger and, if the integrated voltage value meets or exceeds the voltage level trigger, determine to switch states.

If SOC monitor device 1100 determines to switch states, method 1200 proceeds to step 1240. Otherwise, state of charge monitor device 1100 remains in the first state and the first integration circuit 1110 continues updating the integrated voltage value based on received current measurement signals.

At step 1240, SOC monitor device 1100 switches to the second state and SMCD 1130 controls the second integrator circuit 1110 to generate an output based on current measurement signals that represent current into or out of energy source 206. Prior to switching to the second state, SMCD 1130 can reset second integrator circuit 1110 so that second integrator circuit 1110 starts integrating at a value of zero. Second integrator circuit 1110 integrates the current measurement signals while in the second state to generate a second integrated voltage value.

At step 1250, SOC monitor device 1100 obtains an output from the first integrator circuit 1110 of the multiple parallel integrator circuits. While in the second state, first integrator circuit 1110 does not receive current measurements and therefore the output of first integrator circuit 1110 does not change. This provides time for SOC monitor device 1100 to obtain the final first integrated voltage value from the output of first integrator circuit 1110.

At step 1260, SOC monitor device 1100 determines whether to switch (e.g., toggle) from the second state to the first state. SOC monitor device 1100 can determine whether to switch states based on one or more conditions. These conditions can be the same as those described above with respect to step 1230.

If SOC monitor device 1100 determines to change states, method 1200 returns to step 1210 for another iteration of the first state. Otherwise, SOC monitor device 1100 remains in the second state and the first integration circuit 1110 continues updating the integrated voltage value based on received current measurement signals.

At step 1270, SOC monitor device 1100 (or another device, such as MCD 112 or LCD 114) estimates the SOC of energy source 206 based on first and second integrated voltage values output by the first and second integrator circuits. Although shown as occurring after step 1260, SOC monitor device 1100 can estimate the SOC of energy source 206 at any time based on integrated voltage values generated by the first and second integrator circuits. As described above with reference to FIG. 11A, SOC monitor device 1100 (or another device such as MCD 112 or LCD 114) can estimate the SOC based on the integrated voltage values and optionally other signals such as the voltage level of energy source 206, the temperature of energy source, and/or other operating characteristics of energy source 206.

When method 1200 is implemented in an embodiment of system 100, MCD 112 can use the estimated SOCs of energy sources 206 of modules 108 to operate modules 108. For example, MCD 112 can use the estimated SOCs to balance the SOCs of modules 108 in system 100.

Various aspects of the present subject matter are set forth below, in review of, and/or in supplementation to, the embodiments described thus far, with the emphasis here being on the interrelation and interchangeability of the following embodiments. In other words, an emphasis is on the fact that each feature of the embodiments can be combined with each and every other feature unless explicitly stated or taught otherwise or logically implausible.

In many embodiments, an energy system includes one or more arrays of cascaded modules. Each array includes at least two modules electrically connected together to output an AC voltage signal comprising a superposition of output voltages from each of the at least two modules, each module comprising an energy source and a converter. The energy system includes one or more state of charge monitor devices. Each state of charge monitor device includes two or more integrator circuits connected in parallel. Each integrator circuit is coupled to receive current measurement signals for the energy source of a module and generate an integrated voltage value for the energy source based on the current measurement signals. The state of charge monitor device includes a control device configured to selectively switch between a first state in which only a first integrator circuit of the two or more integrator circuits receives the current measurements and generates a first integrated voltage value and a second state in which only a different second integrator circuit of the two or more integrator circuits receives the current measurements and generates a second integrated voltage value. The control device is configured to obtain the second integrated voltage value from the second integrator when the control device is in the first state and to obtain the first integrated voltage value from the first integrator circuit when the control device is in the second state.

In many embodiments, an energy system includes an energy source and a state of charge monitor device configured to monitor state of charge of the energy source. The state of charge monitor device includes two or more integrator circuits connected in parallel. Each integrator circuit is configured to receive current measurement signals for the energy source and generate an integrated voltage value for the energy source based on the current measurement signals. The state of charge monitor device includes a control device configured to selectively switch between a first state in which only a first integrator circuit of the two or more integrator circuits receives the current measurements and generates a first integrated voltage value and a second state in which only a different second integrator circuit of the two or more integrator circuits receives the current measurements and generates a second integrated voltage value. The control device is configured to obtain the second integrated voltage value from the second integrator when the control device is in the first state and to obtain the first integrated voltage value from the first integrator circuit when the control device is in the second state.

In some embodiments, the first integrator circuit is configured to store a final value of the first integrated voltage value when the control device is in the second state. The first integrator circuit is disconnected from a sensing element from which the current measurement signals are received when the control device is in the second state.

In some embodiments, the second integrator circuit is configured to store a final value of the second integrated voltage value when the control device is in the first state. The second integrator circuit is disconnected from a sensing element from which the current measurement signals are received when the control device is in the first state.

In some embodiments, the sensing element is a resistor coupled to the energy source.

In some embodiments, the control device toggles between the first state and the second state based on a specified duration of time.

In some embodiments, the control system remains in the first state for a first time period and in the second state for a second time period, wherein the first time period and the second time period are equal.

In some embodiments, the control device is configured to switch between the first state and the second state in response to an integrated voltage value meeting or exceeding a threshold.

In some embodiments, the control device is configured to switch from the first state to the second state in response to the first integrated voltage value meeting or exceeding the threshold.

In some embodiments, the control device is configured to switch from the second state to the first state in response to the second integrated voltage value meeting or exceeding the threshold.

In some embodiments, the control device is configured to provide each first and second integrated voltage values to another device.

In some embodiments, the control device is configured to estimate a state of charge of the energy source based on each of the first and second integrated voltage values.

In some embodiments, the control device is configured to estimate the state of charge of the energy source based further on a voltage level of the energy source.

In some embodiments, the control device is configured to estimate the state of charge of the energy source based further on operating characteristics of the energy source, wherein the operating characteristics comprises a temperature of the energy source.

In some embodiments, the energy source includes a battery, a battery cell of a battery, or a battery pack.

In some embodiments, the energy system includes a respective state of charge monitor device for each of a plurality of energy sources.

In some embodiments, each integrator circuit includes an operational amplifier-based integration circuit.

In some embodiments, the control system is configured to reset the first integrated voltage value before transitioning to the first state and to reset the second integrated voltage value before transitioning to the second state.

In some embodiments, the state of charge monitor device includes a first switch controllable to selectively route the current measurement signals to the first integrator circuit or the second integrator circuit. Switching states includes switching the first switch between a first position in which the first switch routes the current measurement signals to the first integrator circuit and a second position in which the first switch routes the current measurement signals to the second integrator circuit.

In some embodiments, the state of charge monitor device includes a second switch controllable to selectively route either the first integrated voltage signal or the second integrated voltage signal to the control device.

In many embodiments, a state of charge monitor device is configured to monitor state of charge of an energy source. The state of charge monitor device includes two or more integrator circuits. Each integrator circuit is configured to receive current measurement signals for an energy source and generate an integrated voltage value for the energy source based on the current measurement signals. The state of charge monitor device includes a control device configured to control a first integrator circuit to generate first integrated voltage values based on the current measurement signals during a plurality of first time periods and control a second integrator circuit to generate second integrated voltage values based on the current measurement signals during a plurality of second time periods not overlapping the plurality of first time periods.

In many embodiments, a method of estimating state of charge of an energy source includes operating a multi-integrator circuit that includes a first integrator circuit and a second integrator circuit in a first state, including routing current measurement signals to the first integrator circuit and obtaining a second integrated voltage value from the second integrator circuit while in the first state. The method includes operating the multi-integrator circuit in a second state, including routing current measurement signals to the second integrator circuit and obtaining a first integrated voltage value from the first integrator circuit while in the second state. Each current measurement signal represents a level of current into or from the energy source. The method includes selectively transitioning the multi-integrator circuit between the first and second states and estimating the state of charge of the energy source based at least on one or more first integrated voltage values obtained from the first integrator circuit and one or more second integrated voltage values received from the second integrator circuit.

In some embodiments, selectively transitioning the multi-integrator circuit between the first and second states includes toggling, by a control device, between the first state and the second state based on a specified duration of time.

In some embodiments, the control system remains in the first state for a first time period and in the second state for a second time period. The first time period and the second time period can be equal.

In some embodiments, selectively transitioning the multi-integrator circuit between the first and second states includes switching between the first state and the second state in response to an integrated voltage value meeting or exceeding a threshold.

In some embodiments, switching between the first state and the second state in response to an integrated voltage value meeting or exceeding a threshold includes switching from the first state to the second state in response to the first integrated voltage value meeting or exceeding the threshold.

In some embodiments, switching between the first state and the second state in response to an integrated voltage value meeting or exceeding a threshold includes switching from the second state to the first state in response to the second integrated voltage value meeting or exceeding the threshold.

In some embodiments, estimating the state of charge of the energy source includes estimating the state of charge of the energy source based on a voltage level of the energy source.

In some embodiments, estimating the state of charge of the energy source includes estimating based further on operating characteristics of the energy source. The operating characteristics include a temperature of the energy source.

In some embodiments, the energy source includes a battery, a battery cell of a battery, or a battery pack.

In some embodiments, each integrator circuit includes an operational amplifier-based integration circuit.

In some embodiments, the method include resetting the first integrated voltage value before transitioning to the first state and resetting the second integrated voltage value before transitioning to the second state.

The term “module” as used herein refers to one of two or more devices or sub-systems within a larger system. The module can be configured to work in conjunction with other modules of similar size, function, and physical arrangement (e.g., location of electrical terminals, connectors, etc.). Modules having the same function and energy source(s) can be configured identical (e.g., size and physical arrangement) to all other modules within the same system (e.g., rack or pack), while modules having different functions or energy source(s) may vary in size and physical arrangement. While each module may be physically removable and replaceable with respect to the other modules of the system (e.g., like wheels on a car, or blades in an information technology (IT) blade server), such is not required. For example, a system may be packaged in a common housing that does not permit removal and replacement any one module, without disassembly of the system as a whole. However, any and all embodiments herein can be configured such that each module is removable and replaceable with respect to the other modules in a convenient fashion, such as without disassembly of the system.

The term “output” is used herein in a broad sense, and does not preclude functioning in a bidirectional manner as both an output and an input unless otherwise stated or logically implausible. Similarly, the term “input” is used herein in a broad sense, and does not preclude functioning in a bidirectional manner as both an input and an output otherwise stated or logically implausible.

The terms “terminal” and “port” are used herein in a broad sense, can be either unidirectional or bidirectional, can be an input or an output, and do not require a specific physical or mechanical structure, such as a female or male configuration.

Processing circuitry can include one or more processors, microprocessors, controllers, and/or microcontrollers, each of which can be a discrete or stand-alone chip or distributed amongst (and a portion of) a number of different chips. Any type of processing circuitry can be implemented, such as, but not limited to, personal computing architectures (e.g., such as used in desktop PC's, laptops, tablets, etc.), programmable gate array architectures, proprietary architectures, custom architectures, and others. Processing circuitry can include a digital signal processor, which can be implemented in hardware and/or software. Processing circuitry can execute software instructions stored on memory that cause processing circuitry to take a host of different actions and control other components.

Processing circuitry can also perform other software and/or hardware routines. For example, processing circuitry can interface with communication circuitry and perform analog-to-digital conversions, encoding and decoding, other digital signal processing, multimedia functions, conversion of data into a format (e.g., in-phase and quadrature) suitable for provision to communication circuitry, and/or can cause communication circuitry to transmit the data (wired or wirelessly).

Processing circuitry can also be adapted to execute the operating system and any software applications, and perform those other functions not related to the processing of communications transmitted and received.

Computer program instructions for carrying out operations in accordance with the described subject matter may be written in any combination of one or more programming languages, including computer and programming languages. A non-exhaustive list of examples includes hardware description languages (HDLs), SystemC, C, C++, C #, Objective-C, Matlab, Simulink, System Verilog, System VHDL, Handel-C, Python, Java, JavaScript, Ruby, HTML, Smalltalk, Transact-SQL, XML, PHP, Golang (Go), “R” language, and Swift, to name a few.

Memory, storage, and/or computer readable media can be shared by one or more of the various functional units present, or can be distributed amongst two or more of them (e.g., as separate memories present within different chips). Memory can also reside in a separate chip of its own.

To the extent the embodiments disclosed herein include or operate in association with memory, storage, and/or computer readable media, then that memory, storage, and/or computer readable media are non-transitory. Accordingly, to the extent that memory, storage, and/or computer readable media are covered by one or more claims, then that memory, storage, and/or computer readable media is only non-transitory. The terms “non-transitory” and “tangible” as used herein, are intended to describe memory, storage, and/or computer readable media excluding propagating electromagnetic signals, but are not intended to limit the type of memory, storage, and/or computer readable media in terms of the persistency of storage or otherwise. For example, “non-transitory” and/or “tangible” memory, storage, and/or computer readable media encompasses volatile and non-volatile media such as random access media (e.g., RAM, SRAM, DRAM, FRAM, etc.), read-only media (e.g., ROM, PROM, EPROM, EEPROM, flash, etc.) and combinations thereof (e.g., hybrid RAM and ROM, NVRAM, etc.) and variants thereof.

It should be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

While the embodiments are susceptible to various modifications and alternative forms, specific examples thereof have been shown in the drawings and are herein described in detail. It should be understood, however, that these embodiments are not to be limited to the particular form disclosed.

1. An energy system, comprising:
one or more arrays of cascaded modules, each array comprising at least two modules electrically connected together to output an AC voltage signal comprising a superposition of output voltages from each of the at least two modules, each module comprising an energy source and a converter; and
one or more state of charge monitor devices, each state of charge monitor device comprising:
two or more integrator circuits connected in parallel, each integrator circuit being coupled to receive current measurement signals for the energy source of a module and generate an integrated voltage value for the energy source based on the current measurement signals; and
a control device configured to:
selectively switch between (i) a first state in which only a first integrator circuit of the two or more integrator circuits receives the current measurements and generates a first integrated voltage value and (ii) a second state in which only a different second integrator circuit of the two or more integrator circuits receives the current measurements and generates a second integrated voltage value; and
obtain the second integrated voltage value from the second integrator when the control device is in the first state and to obtain the first integrated voltage value from the first integrator circuit when the control device is in the second state.

2. An energy system comprising:
an energy source; and
a state of charge monitor device configured to monitor state of charge of the energy source, the state of charge monitor device comprising:
two or more integrator circuits connected in parallel, each integrator circuit being configured to receive current measurement signals for the energy source and generate an integrated voltage value for the energy source based on the current measurement signals; and
a control device configured to:
selectively switch between (i) a first state in which only a first integrator circuit of the two or more integrator circuits receives the current measurements and generates a first integrated voltage value and (ii) a second state in which only a different second integrator circuit of the two or more integrator circuits receives the current measurements and generates a second integrated voltage value; and
obtain the second integrated voltage value from the second integrator when the control device is in the first state and to obtain the first integrated voltage value from the first integrator circuit when the control device is in the second state.

3. The energy system of claim 1 or claim 2, wherein the first integrator circuit is configured to store a final value of the first integrated voltage value when the control device is in the second state, and wherein the first integrator circuit is disconnected from a sensing element from which the current measurement signals are received when the control device is in the second state.

4. The energy system of any one of claims 1-3, wherein the second integrator circuit is configured to store a final value of the second integrated voltage value when the control device is in the first state, and wherein the second integrator circuit is disconnected from a sensing element from which the current measurement signals are received when the control device is in the first state.

5. The energy system of any one of claim 3 or 4, wherein the sensing element is a resistor coupled to the energy source.

6. The energy system of any one of claims 1-5, wherein the control device toggles between the first state and the second state based on a specified duration of time.

7. The energy system of any one of claims 1-6, wherein the control system remains in the first state for a first time period and in the second state for a second time period, wherein the first time period and the second time period are equal.

8. The energy system of claim 7, wherein the control device is configured to switch between the first state and the second state in response to an integrated voltage value meeting or exceeding a threshold.

9. The energy system of claim 8, wherein the control device is configured to switch from the first state to the second state in response to the first integrated voltage value meeting or exceeding the threshold.

10. The energy system of claim 8 or 9, wherein the control device is configured to switch from the second state to the first state in response to the second integrated voltage value meeting or exceeding the threshold.

11. The energy system of any preceding claim, wherein the control device is configured to provide each first and second integrated voltage values to another device.

12. The energy system of any preceding claim, wherein the control device is configured to estimate a state of charge of the energy source based on each of the first and second integrated voltage values.

13. The energy system of claim 12, wherein the control device is configured to estimate the state of charge of the energy source based further on a voltage level of the energy source.

14. The energy system of claim 12 or 13, wherein the control device is configured to estimate the state of charge of the energy source based further on operating characteristics of the energy source, wherein the operating characteristics comprises a temperature of the energy source.

15. The energy system of any preceding claim, wherein the energy source comprises a battery, a battery cell of a battery, or a battery pack.

16. The energy system of any preceding claim, comprising a respective state of charge monitor device for each of a plurality of energy sources.

17. The energy system of any preceding claim, wherein each integrator circuit comprises an operational amplifier-based integration circuit.

18. The energy system of any preceding claim, wherein the control system is configured to reset the first integrated voltage value before transitioning to the first state and to reset the second integrated voltage value before transitioning to the second state.

19. The energy system of any preceding claim, comprising a first switch controllable to selectively route the current measurement signals to the first integrator circuit or the second integrator circuit and wherein switching states comprises switching the first switch between a first position in which the first switch routes the current measurement signals to the first integrator circuit and a second position in which the first switch routes the current measurement signals to the second integrator circuit.

20. The energy system of any preceding claim, comprising a second switch controllable to selectively route either the first integrated voltage signal or the second integrated voltage signal to the control device.

21. A state of charge monitor device configured to monitor state of charge of an energy source, the state of charge monitor device comprising:
two or more integrator circuits, each integrator circuit being configured to receive current measurement signals for an energy source and generate an integrated voltage value for the energy source based on the current measurement signals; and
a control device configured to:
control a first integrator circuit to generate first integrated voltage values based on the current measurement signals during a plurality of first time periods; and
control a second integrator circuit to generate second integrated voltage values based on the current measurement signals during a plurality of second time periods not overlapping the plurality of first time periods.

22. A method of estimating state of charge of an energy source, the method comprising:
operating a multi-integrator circuit comprising a first integrator circuit and a second integrator circuit in a first state, including routing current measurement signals to the first integrator circuit and obtaining a second integrated voltage value from the second integrator circuit while in the first state;
operating the multi-integrator circuit in a second state, including routing current measurement signals to the second integrator circuit and obtaining a first integrated voltage value from the first integrator circuit while in the second state, wherein each current measurement signal represents a level of current into or from the energy source;
selectively transitioning the multi-integrator circuit between the first and second states; and
estimating the state of charge of the energy source based at least on one or more first integrated voltage values obtained from the first integrator circuit and one or more second integrated voltage values received from the second integrator circuit.

23. The method of claim 22, wherein selectively transitioning the multi-integrator circuit between the first and second states comprises toggling, by a control device, between the first state and the second state based on a specified duration of time.

24. The method of claim 23, wherein the control system remains in the first state for a first time period and in the second state for a second time period, wherein the first time period and the second time period are equal.

25. The method of claim 22, wherein selectively transitioning the multi-integrator circuit between the first and second states comprises switching between the first state and the second state in response to an integrated voltage value meeting or exceeding a threshold.

26. The method of claim 25, wherein switching between the first state and the second state in response to an integrated voltage value meeting or exceeding a threshold comprises switching from the first state to the second state in response to the first integrated voltage value meeting or exceeding the threshold.

27. The method of claim 24 or 25, wherein switching between the first state and the second state in response to an integrated voltage value meeting or exceeding a threshold comprises switching from the second state to the first state in response to the second integrated voltage value meeting or exceeding the threshold.

28. The method of any one of claims 22-27, wherein estimating the state of charge of the energy source comprises estimating the state of charge of the energy source based further on a voltage level of the energy source.

29. The method of any one of claims 22-27, wherein estimating the state of charge of the energy source comprises estimating based further on operating characteristics of the energy source, wherein the operating characteristics comprise a temperature of the energy source.

30. The method of any one of claims 22-29, wherein the energy source comprises a battery, a battery cell of a battery, or a battery pack.

31. The method of any one of claims 22-30, wherein each integrator circuit comprises an operational amplifier-based integration circuit.

32. The method of any one of claims 22-31, further comprising resetting the first integrated voltage value before transitioning to the first state and resetting the second integrated voltage value before transitioning to the second state.
